(19) United States
(12) Patent Application Publication
(10) Pub. No.: US 2025/0126860 A1
(43) Pub. Date: Apr. 17, 2025

(54) INTEGRATED CIRCUIT DEVICE

(71) Applicant: SAMSUNG ELECTRONICS CO., LTD., SUWON-SI (KR)

(72) Inventors: Jaehyun AHN, Suwon-si (KR); Jinkyu KIM, Suwon-si (KR); Hidenobu FUKUTOME, Suwon-si (KR); Jeewoong KIM, Suwon-si (KR); Yunsuk NAM, Suwon-si (KR)

(21) Appl. No.: 18/738,594

(22) Filed: Jun. 10, 2024

(30) Foreign Application Priority Data
Oct. 17, 2023 (KR) 10-2023-0138920

(51) Int. Cl. H01L 29/08; H01L 23/528; H01L 27/088; H01L 29/06; H01L 29/417; H01L 29/423; H01L 29/775; H01L 29/786

(52) U.S. Cl. CPC H10D 62/151; H01L 23/5286; H10D 30/43; H10D 30/6729; H10D 30/6735; H10D 30/6757; H10D 62/121; H10D 84/83

(57) ABSTRACT

An integrated circuit device includes: a substrate including a first surface and a second surface; a fin-type active area extending on the first surface of the substrate in a first horizontal direction, and including a first area and a second area that are adjacent to each other; a first source/drain area arranged on the first area of the fin-type active area; a second source/drain area arranged on the second area of the fin-type active area; and a first filling insulating layer extending between the first source/drain area and the second source/drain area, wherein the first area includes a first conductivity type, wherein the second area includes a second conductivity type that is different from the first conductivity type, and wherein a boundary between the first area and the second area includes a portion that is substantially perpendicular to the first horizontal direction, and overlaps the filling insulating layer.

### CROSS-REFERENCE TO RELATED APPLICATION

This application claims priority under 35 U.S.C. § 119 to Korean Patent Application No. 10-2023-0138920, filed on Oct. 17, 2023, in the Korean Intellectual Property office, the disclosure of which is incorporated by reference herein in its entirety.

### TECHNICAL FIELD

Embodiments of present inventive concept relates to an integrated circuit device, and more particularly, to an integrated circuit device formed by a self-alignment method.

### DISCUSSION OF THE RELATED ART

As electronic products are desired to be miniaturized, multifunctional, and have high-performance, there is also a demand for circuit devices having high capacity and high integration. Accordingly, to achieve high integration while securing functions and operation speed for the integrated circuit devices, an efficient design of wiring structures is desired.

### SUMMARY

According to an embodiment of the present inventive concept, an integrated circuit device includes: a substrate including a first surface and a second surface that are opposite to each other; a fin-type active area extending on the first surface of the substrate in a first horizontal direction, and including a first area and a second area that are adjacent to each other in the first horizontal direction; a first source/drain area arranged on the first area of the fin-type active area; a second source/drain area arranged on the second area of the fin-type active area; and a first filling insulating layer, which extends in a second horizontal direction crossing the first horizontal direction, between the first source/drain area and the second source/drain area, wherein the first area of the fin-type active area includes a first conductivity type, wherein the second area of the fin-type active area includes a second conductivity type that is different from the first conductivity type, and wherein a boundary between the first area and the second area of the fin-type active area includes a portion that is substantially perpendicular to the first horizontal direction, and overlaps the filling insulating layer.

According to an embodiment of the present inventive concept, an integrated circuit device includes: a substrate including a first surface and a second surface that are opposite to each other; a fin-type active area extending on the first surface of the substrate in a first horizontal direction, and including a first area and a second area that are adjacent to each other in the first horizontal direction; a first source/drain area arranged on the first area of the fin-type active area; a second source/drain area arranged on the second area of the fin-type active area; a filling insulating layer, which extends in a second horizontal direction crossing the first horizontal direction, between the first source/drain area and the second source/drain area; and a power pad and a ground pad, each of which are arranged on the second surface of the substrate, wherein each of the first area of the fin-type active area and the first source/drain area includes a first conductivity type, wherein each of the second area of the fin-type active area and the second source/drain area includes a second conductivity type that is different from the first conductivity type, and wherein a current path is formed in the fin-type active area in the first horizontal direction.

According to an embodiment of the present inventive concept, an integrated circuit device includes: a substrate including a first surface and a second surface that are opposite to each other; a fin-type active area extending on the first surface of the substrate in a first horizontal direction, wherein the fin-type active area includes a first area, a second area, and a third area that is spaced apart from the second area with the first area disposed therebetween, wherein the first, second and third areas are arranged in the first horizontal direction; a first source/drain area arranged on the first area of the fin-type active area; a second source/drain area arranged on the second area of the fin-type active area; a third source/drain area arranged on the third area of the fin-type active area; a filling insulating layer extending between the first source/drain area and the second source/drain area and between the second source/drain area and the third source/drain area; and a power pad and a ground pad, each of which are arranged on the second surface of the substrate, wherein the first area of the fin-type active area includes a first conductivity type, wherein each of the second area and the third area of the fin-type active area includes a second conductivity type that is different from the first conductivity type, wherein the first source/drain area includes the first conductivity type, wherein each of the second source/drain area and the third source/drain area includes the second conductivity type, and wherein each of a boundary between the first area and the second area and a boundary between the first area and the third area of the fin-type active area includes a portion that is substantially perpendicular to the first horizontal direction, and overlaps the filling insulating layer.

### BRIEF DESCRIPTION OF THE DRAWINGS

The above and other aspects of the present inventive concept will become more apparent by describing in detail embodiments thereof, with reference to the accompanying drawings, in which:

FIG. 1 is a plan layout diagram of an integrated circuit device according to an embodiment of the present inventive concept;

FIGS. 2A and 2B are cross-sectional views of an integrated circuit device according to embodiments of the present inventive concept;

FIG. 3 is a cross-sectional view of an integrated circuit device according to an embodiment of the present inventive concept;

FIGS. 4A, 4B, 4C and 4D are cross-sectional views of an integrated circuit device according to embodiments of the present inventive concept;

FIGS. 5A, 5B, 5C and 5D are cross-sectional views of an integrated circuit device according to embodiments of the present inventive concept;

FIGS. 6A and 6B are cross-sectional views of an integrated circuit device according to embodiments of the present inventive concept;

FIGS. 7A, 7B, 7C, 7D, 7E, 7F, 7G, 7H, 7I, 7J, 7K, 7L, 7M, 7N and 7O are cross-sectional views illustrating a method of manufacturing an integrated circuit device, according to embodiments of the present inventive concept;

FIGS. 8A, 8B, 8C and 8D are cross-sectional views illustrating a method of manufacturing an integrated circuit device, according to embodiments of the present inventive concept; and

FIGS. 9A, 9B, 9C, and 9D are cross-sectional views of integrated circuit device according to embodiments.

### DETAILED DESCRIPTION OF THE EMBODIMENTS

Hereinafter, embodiments of the present inventive concept will be described in detail with reference to the accompanying drawings. Identical reference numerals are used for the same elements in the specification and drawings, and duplicate descriptions thereof may be omitted or briefly discussed.

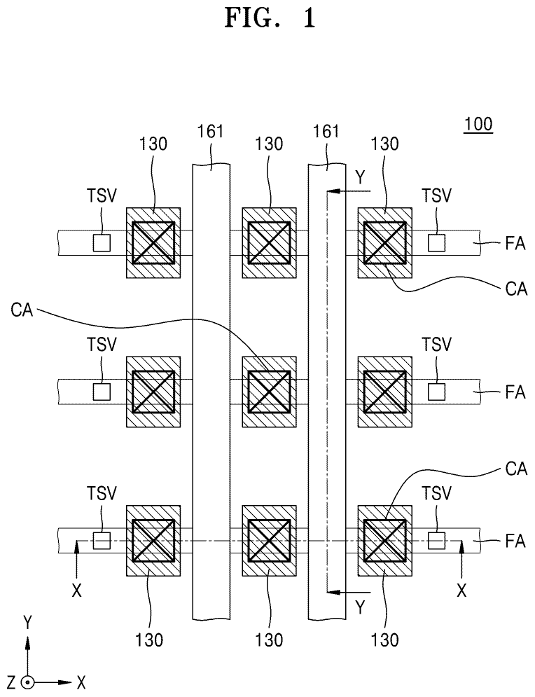

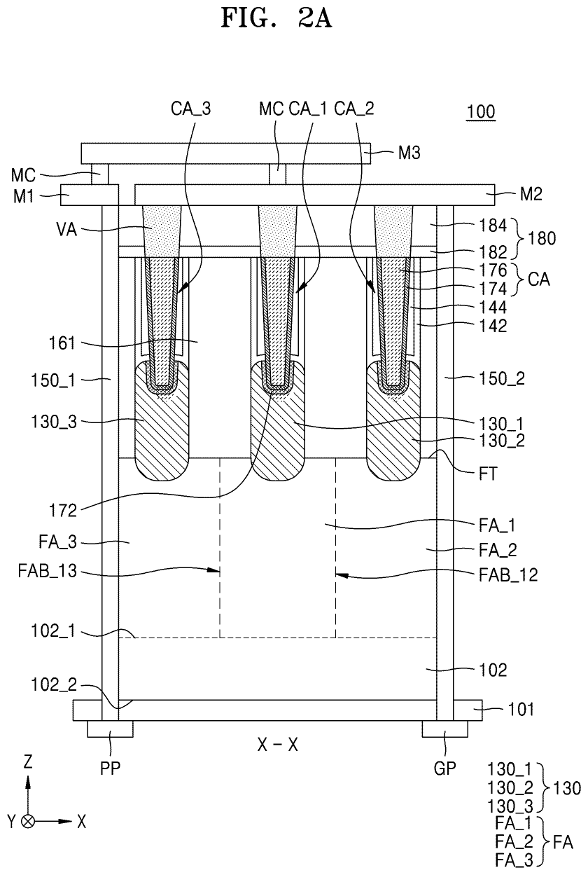

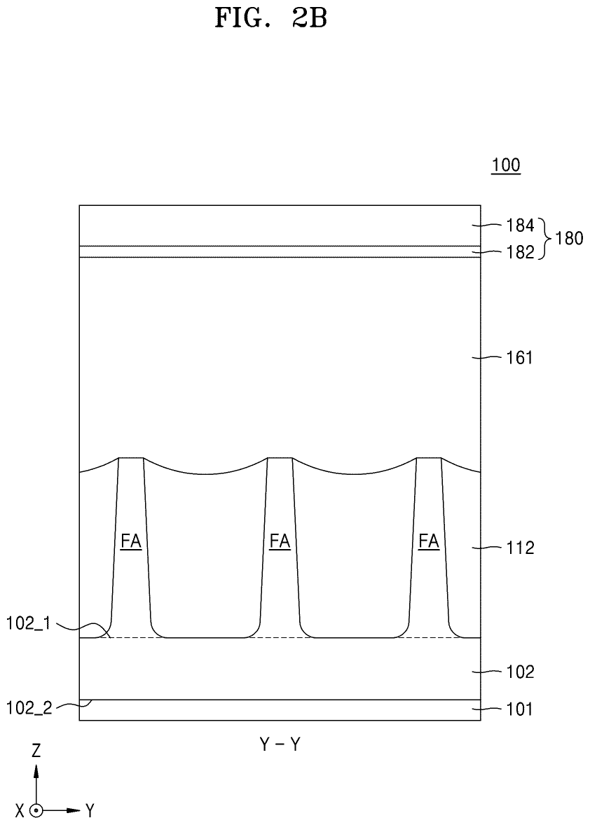

FIG. 1 is a plan layout diagram of an integrated circuit device 100 according to an embodiment of the present inventive concept. FIGS. 2A and 2B are cross-sectional views of example configurations of an integrated circuit device 100, according to embodiments of the present inventive concept. FIG. 2A is a cross-sectional view taken along line X-X in FIG. 1. FIG. 2B is a cross-sectional view taken along line Y-Y in FIG. 1.

Referring to FIGS. 1, 2A, and 2B, the integrated circuit device 100 may include a substrate 102, which has a first surface 102_1 and a second surface 102_2, and a plurality of fin-type active areas FA that protrudes from an upper surface of the first surface 102_1 of the substrate 102. The plurality of fin-type active areas FA may extend long on the substrate 102 in a first horizontal direction (X direction), and may extend in parallel with each other.

In embodiments of the present inventive concept, the substrate 102 may include a semiconductor, such as Si and Ge, or a compound semiconductor, such as SiGe, SiC, GaAs, InAs, InGaAs, and InP. The terms “SiGe”, “SiC”, “GaAs”, “InAs”, “InGaAs”, and “InP” used in the present inventive concept may be referred to as materials including elements included in each term, but might not be referred to as chemical formulas representing a stoichiometric relationship. The substrate 102 may include a conductive area, for example, a well doped with impurities, or a structure doped with impurities.

As illustrated in FIG. 2B, a device isolation layer 112 may be arranged in a trench which limits the plurality of fin-type active areas FA. For example, the device isolation layer 112 may be formed in a trench that is formed between two neighboring fin-type active areas FA. The device isolation layer 112 may cover a portion of sidewalls of each of the plurality of fin-type active areas FA, and may be spaced apart from the substrate 102 in a vertical direction (Z direction). The device isolation layer 112 may include, for example, a silicon oxide layer. The device isolation layer 112 may include a material having different etching selectivity from the substrate 102.

As illustrated in FIG. 2A, the fin-type active area FA may include a plurality of doped areas arranged in the first horizontal direction (X direction), that is, a first area FA_1, a second area FA_2, and a third area FA_3.

The first area FA_1 may be arranged between the second area FA_2 and the third area FA_3, and may be adjacent to the second area FA_2 and the third area FA_3. According to embodiments of the present inventive concept, when the first area FA_1 is adjacent to the second area FA_2 and/or the third area FA_3, although the first area FA_1 is not directly in contact with the second area FA_2 and/or the third area FA_3, it may mean that the first area FA_1 is arranged relatively close to them. The second area FA_2 may be spaced apart from the third area FA_3 with the first area FA_1 disposed therebetween, and may be adjacent to the first area FA_1. The third area FA_3 may be spaced apart from the second area FA_2 with the first area FA_1 disposed therebetween, and may be adjacent to the first area FA_1.

For example, the first area FA_1 may be in contact with the second area FA_2 and the third area FA_3. In embodiments of the present inventive concept, when the first area FA_1 is in contact with the second area FA_2 and/or the third area FA_3, it may mean that the first area FA_1 shares a boundary with each of the second area FA_2 and/or the third area FA_3.

In embodiments of the present inventive concept, the fin-type active area FA may include a plurality of doped areas including different conductivity types from each other. The first area FA_1 and the second area FA_2 may include different conductivity types from each other. For example, the first area FA_1 may include a first conductivity type, and the second area FA_2 may include a second conductivity type that is different from the first conductivity type. The first area FA_1 and the third area FA_3 may include different conductivity types from each other. For example, the first area FA_1 may include a first conductivity type, and the third area FA_3 may include a second conductivity type that is different from the first conductivity type.

In embodiments of the present inventive concept, the fin-type active area FA may include a plurality of doped areas including the same conductivity type. The second area FA_2 and the third area FA_3 may include the same conductivity type as each other. For example, both the second area FA_2 and the third area FA_3 may include the second conductivity type. In other words, the second area FA_2 and the third area FA_3 may be spaced apart from each other with the first area FA_1 disposed therebetween, and the second area FA_2 and the third area FA_3 may include the same conductivity type as each other. In other words, both the second area FA_2 and the third area FA_3, which are spaced apart from each other with the first area FA_1 therebetween, may include a second conductivity type, while the first area FA_1 includes the first conductivity type.

In an embodiment of the present inventive concept, while the first area FA_1 is doped with an N-type, the second area FA_2 and the third area FA_3 may be doped with a P-type. In an embodiment of the present inventive concept, while the first area FA_1 is doped with a P-type, the second area FA_2 and the third area FA_3 may each be doped with an N-type.

As illustrated in FIG. 2A, a boundary between doped areas adjacent to each other among the plurality of doped areas may be perpendicular to the first horizontal direction (X direction). A boundary FAB_12 between the first area FA_1 and the second area FA_2, which are adjacent to each other, may be perpendicular to the first horizontal direction (X direction). For example, the boundary FAB_12 between the first area FA_1 and the second area FA_2 may be in parallel with a Y-Z flat surface (e.g., a plane), and perpendicular to the first horizontal direction (X direction). A boundary FAB_13 between the first area FA_1 and the third area FA_3, which are adjacent to each other, may be perpendicular to the first horizontal direction (X direction). For example, the boundary FAB_13 between the first area FA_1 and the third area FA_3 may be in parallel with the Y-Z flat surface, and perpendicular to the first horizontal direction (X direction).

In embodiments of the present inventive concept, a boundary between doped areas that are adjacent to each other among the plurality of doped areas may include a portion that is substantially perpendicular to the first horizontal direction (X direction). The boundary FAB_12 between the first area FA_1 and the second area FA_2, which are adjacent to each other, may include a portion substantially perpendicular to the first horizontal direction (X direction). The boundary FAB_13 between the first area FA_1 and the third area FA_3, which are adjacent to each other, may include a portion substantially perpendicular to the first horizontal direction (X direction).

In embodiments of the present inventive concept, a current path may be formed by two doped areas adjacent to each other and including different conductivity types from each other. A current path may be formed between the first area FA_1 and the second area FA_2, which are adjacent to each other and include different conductivity types from each other. For example, a current may flow from the first area FA_1 to the second area FA_2. For example, a current may flow from the second area FA_2 to the first area FA_1. A current path may be formed between the first area FA_1 and the third area FA_3, which are adjacent to each other and include different conductivity types from each other. For example, a current may flow from the first area FA_1 to the third area FA_3. For example, a current may flow from the third area FA_3 to the first area FA_1.

In embodiments of the present inventive concept, in the fin-type active area FA, the current path may be formed to cross a boundary between two doped areas that are adjacent to each other. In other words, in the fin-type active area FA, a current may flow across a boundary between two doped areas that are adjacent to each other. As described above, a boundary between the adjacent doped areas among the plurality of doped areas may be perpendicular to the first horizontal direction (X direction), and accordingly, in the fin-type active area FA, the current path may be formed in the first horizontal direction (X direction).

The current path between the first area FA_1 and the second area FA_2 that are adjacent to each other may be formed in the first horizontal direction (X direction). For example, the current path flowing from the first area FA_1 to the second area FA_2 may be formed in the first horizontal direction (X direction). For example, the current path flowing from the second area FA_2 to the first area FA_1 may be formed in the first horizontal direction (X direction).

The current path between the first area FA_1 and the third area FA_3 that are adjacent to each other may be formed in the first horizontal direction (X direction). For example, the current path flowing from the first area FA_1 to the third area FA_3 may be formed in the first horizontal direction (X direction). For example, the current path flowing from the third area FA_3 to the first area FA_1 may be formed in the first horizontal direction (X direction).

In embodiments of the present inventive concept, in the fin-type active area FA, the current path may include a current path formed in the first horizontal direction (X direction). The current path between the first area FA_1 and the second area FA_2 that are adjacent to each other may include a current path formed in the first horizontal direction (X direction). The current path between the first area FA_1 and the third area FA_3 that are adjacent to each other may include a current path formed in the first horizontal direction (X direction).

According to embodiments of the present inventive concept, the integrated circuit device 100 including the plurality of doped areas that are adjacent to each other in the first horizontal direction (X direction), for example, the first area FA_1 and the second area FA_2 in the fin-type active area FA may be provided. As the integrated circuit device 100 according to embodiments of the present inventive concept includes a plurality of doped areas that are adjacent to each other, in a process of fabricating the integrated circuit device 100, a current may flow between the plurality of doped areas even though the substrate 102 is thinned. In other words, the integrated circuit device 100 having increased performance and reliability may be provided, according to embodiments of the present inventive concept.

As illustrated in FIG. 2A, a plurality of recesses may be formed in the fin-type active area FA. A vertical level of the lowermost surface of each of the plurality of recesses may be lower than a vertical level of a fin upper surface FT.

As illustrated in FIG. 2A, in the plurality of recesses, a plurality of source/drain areas 130 may be respectively arranged. The plurality of source/drain areas 130 may be arranged in the first horizontal direction (X direction), and may include a first source/drain area 130_1, a second source/drain area 130_2, and a third source/drain area 130_3.

The first source/drain area 130_1 may be arranged between the second source/drain area 130_2 and the third source/drain area 130_3, and may be adjacent to the second source/drain area 130_2 and the third source/drain area 130_3. The second source/drain area 130_2 may be spaced apart from the third source/drain area 130_3 with the first source/drain area 130_1 disposed therebetween, and may be adjacent to the first source/drain area 130_1. The third source/drain area 130_3 may be spaced apart from the second source/drain area 130_2 with the first source/drain area 130_1 disposed therebetween, and may be adjacent to the first source/drain area 130_1.

As illustrated in FIG. 2A, the plurality of source/drain areas 130 may be arranged on the fin-type active area FA. The plurality of source/drain areas 130 may be arranged in contact with the fin-type active area FA. Each of the plurality of source/drain areas 130 may be arranged on each of the plurality of doped areas of the fin-type active area FA. Each of the plurality of source/drain areas 130 may be arranged in contact with the plurality of doped areas of the fin-type active area FA, respectively.

The first source/drain area 130_1 may be arranged on the first area FA_1. The first source/drain area 130_1 may be arranged in contact with the first area FA_1. The second source/drain area 130_2 may be arranged on the second area FA_2. The second source/drain area 130_2 may be arranged in contact with the second area FA_2. The third source/drain area 130_3 may be arranged on the third area FA_3. The third source/drain area 130_3 may be arranged in contact with the third area FA_3.

In embodiments of the present inventive concept, a portion of the plurality of source/drain areas 130 may include different conductivity types from each other. The first source/drain area 130_1 and the second source/drain area 130_2 may include different conductivity types from each other. For example, the first source/drain area 130_1 may include a first conductivity type, and the second source/drain area 130_2 may include a second conductivity type different from the first conductivity type. The first source/drain area 130_1 and the third source/drain area 130_3 may include different conductivity types from each other. For example, the first source/drain area 130_1 may include a first conductivity type, and the third source/drain area 130_3 may include a second conductivity type that is different from the first conductivity type.

In embodiments of the present inventive concept, a portion of the plurality of source/drain areas 130 may include the same conductivity type as each other. The second source/drain area 130_2 and the third source/drain area 130_3 may include the same conductivity type as each other. For example, both the second source/drain area 130_2 and the third source/drain area 130_3 may include the second conductivity type. In other words, the second source/drain area 130_2 and the third source/drain area 130_3, which are spaced apart from each other with the first source/drain area 130_1 disposed therebetween, may include the same conductivity type as each other. In other words, both the second source/drain area 130_2 and the third source/drain area 130_3 include a second conductivity type while the first source/drain area 130_1 includes the first conductivity type.

In embodiments of the present inventive concept, some doped areas of the fin-type active area FA and the source/drain area 130 adjacent to each other may include the same conductivity type as each other. Both the first area FA_1 of the fin-type active area FA and the first source/drain area 130_1 that are adjacent to each other may include a first conductivity type. Both the second area FA_2 of the fin-type active area FA and the second source/drain area 130_2 that are adjacent to each other may include a second conductivity type. Both the third area FA_3 of the fin-type active area FA and the third source/drain area 130_3 that are adjacent to each other may include a second conductivity type.

In embodiments of the present inventive concept, each of the plurality of source/drain areas 130 may be doped with a higher concentration than a dopant of a portion of the fin-type active area FA that is in contact with each of the plurality of source/drain areas 130. The first area FA_1 of the fin-type active area FA may be doped at first concentration, and the first source/drain area 130_1 that is in contact with the first area FA_1 may be doped at a second concentration that is higher than the first concentration. The second area FA_2 of the fin-type active area FA may be doped at third concentration, and the second source/drain area 130_2 that is in contact with the second area FA_2 may be doped at a fourth concentration that is higher than the third concentration. The third area FA_3 of the fin-type active area FA may be doped at fifth concentration, and the third source/drain area 130_3 that is in contact with the third area FA_3 may be doped at a sixth concentration that is higher than the fifth concentration.

In an embodiment of the present inventive concept, while the first source/drain area 130_1 may be doped with an N-type, the second source/drain area 130_2 and the third source/drain area 130_3 may be doped with a P-type. For example, when the first area FA_1 is doped with an N-type and the second area FA_2 and the third area FA_3 are doped with a P-type, the first source/drain area 130_1 may be doped with an N-type, and the second source/drain area 130_2 and the third source/drain area 130_3 may be doped with a P-type.

In an embodiment of the present inventive concept, while the first source/drain area 130_1 is doped with a P-type, the second source/drain area 130_2 and the third source/drain area 130_3 may be doped with an N-type. For example, when the first area FA_1 is doped with a P-type and the second area FA_2 and the third area FA_3 are doped with an N-type, the first source/drain area 130_1 may be doped with a P-type, and the second source/drain area 130_2 and the third source/drain area 130_3 may be doped with an N-type.

As illustrated in FIGS. 2A and 2B, a plurality of filling insulating layers 161 may extend in a second horizontal direction (Y direction) and may be arranged between each of the plurality of source/drain areas 130. The filling insulating layer 161 may be arranged between the first source/drain area 130_1 and the second source/drain area 130_2. The filling insulating layer 161 may be arranged between the first source/drain area 130_1 and the third source/drain area 130_3.

In embodiments of the present inventive concept, each of a plurality of source/drain areas 130 may be spaced apart from each other with the plurality of filling insulating layers 161 arranged therebetween. The first source/drain area 130_1 and the second source/drain area 130_2 may be spaced apart from each other with the filling insulating layer 161 disposed therebetween. The first source/drain area 130_1 and the third source/drain area 130_3 may be spaced apart from each other with the filling insulating layer 161 disposed therebetween.

According to embodiments of the present inventive concept, the integrated circuit device 100 including the filling insulating layer 161 that extends in the second horizontal direction (Y direction) between each of the neighboring source drain areas 130 of the plurality of source/drain areas 130. Because the integrated circuit device 100 according to embodiments of the present inventive concept includes the filling insulating layer 161 arranged between each of the plurality of source/drain areas 130, a leakage current that may occur between each of the plurality of source/drain areas 130 may be prevented. In other words, the integrated circuit device 100 having increased performance and reliability may be provided, according to embodiments of the present inventive concept.

As illustrated in FIG. 2A, a boundary between doped areas that are adjacent to each other among the plurality of doped areas of the fin-type active area FA may overlap the filling insulating layer 161 in the vertical direction (Z direction). The boundary FAB_12 that is between the first area FA_1 and the second area FA_2, which are adjacent to each other, may overlap the filling insulating layer 161 in the vertical direction (Z direction). The boundary FAB_13 that is between the first area FA_1 and the third area FA_3, which are adjacent to each other, may overlap the filling insulating layer 161 in the vertical direction (Z direction).

In embodiments of the present inventive concept, a boundary between doped areas that are adjacent to each other among the plurality of doped areas may overlap the filling insulating layer 161 in the vertical direction (Z direction). The boundary FAB_12 that is between the first area FA_1 and the second area FA_2, which are adjacent to each other, may include a portion overlapping the filling insulating layer 161 in the vertical direction (Z direction). The boundary FAB_13 between the first area FA_1 and the third area FA_3, which are adjacent to each other, may include a portion overlapping the filling insulating layer 161 in the vertical direction (Z direction).

A metal silicide layer 172 may be formed on an upper surface of each of the plurality of source/drain areas 130. The metal silicide layer 172 may include a metal. For example, the metal silicide layer 172 may include at least one of Ti, W, Ru, Nb, Mo, Hf, Ni, Co, Pt, Yb, Tb, Dy, Er, and/or Pd. For example, the metal silicide layer 172 may include titanium silicide, but the present inventive concept is not limited thereto.

The plurality of source/drain areas 130 and a plurality of metal silicide layers 172 may be covered with an insulating liner 142 on the substrate 102. In embodiments of the present inventive concept, the insulating liner 142 may be omitted. An inter-gate insulating layer 144 may be arranged on the insulating liner 142. When the insulating liner 142 is omitted, the inter-gate insulating layer 144 may be in contact with the plurality of source/drain areas 130.

The insulating liner 142 and the inter-gate insulating layer 144 may be sequentially arranged on the plurality of source/drain areas 130 and the plurality of metal silicide layers 172. The insulating liner 142 and the inter-gate insulating layer 144 may constitute an insulating structure. In embodiments of the present inventive concept, the insulating liner 142 may include silicon nitride, SiCN, SiBN, SION, SiOCN, SiBCN, or a combination thereof, but the present inventive concept is not limited thereto. The inter-gate insulating layer 144 may include a silicon oxide layer, but the present inventive concept is not limited thereto.

As illustrated in FIG. 2A, a plurality of source/drain contacts CA may be arranged on the plurality of source/drain areas 130. Each of the plurality of source/drain contacts CA may penetrate the inter-gate insulating layer 144 and the insulating liner 142 in the vertical direction (Z direction), and may be disposed on the metal silicide layer 172. For example, each of the plurality of source/drain contacts CA may contact the metal silicide layer 172. Each of the plurality of source/drain contacts CA may be configured to be electrically connected to the source/drain area 130 via the metal silicide layer 172. For example, the plurality of source/drain contacts CA may include a first source/drain contact CA_1, a second source/drain contact CA_2, and a third source/drain contact CA_3, which are arranged on the first source/drain area 130_1.

The plurality of source/drain contacts CA may include a conductive barrier pattern 174 and a contact plug 176, which are sequentially stacked on the source/drain area 130. The conductive barrier pattern 174 may at least partially surround a lower surface and sidewalls of the contact plug 176. For example, the conductive barrier pattern 174 may be in contact with the lower surface and the sidewalls of the contact plug 176. Each of the plurality of source/drain contacts CA may penetrate the inter-gate insulating layer 144 and the insulating liner 142, and extend long in the vertical direction (Z direction). The conductive barrier pattern 174 may be arranged between the metal silicide layer 172 and the contact plug 176. For example, the conductive barrier pattern 174 may include a first surface, which is in contact with the metal silicide layer 172, and a second surface, which is in contact with the contact plug 176. In embodiments of the present inventive concept, the conductive barrier pattern 174 may include a metal or metal nitride. For example, the conductive barrier pattern 174 may include Ti, Ta, W, TiN, TaN, WN, WCN, TiSiN, TaSiN, WSiN, or a combination thereof, but the present inventive concept is not limited thereto. The contact plug 176 may include, for example, molybdenum (Mo), copper (Cu), tungsten (W), cobalt (Co), ruthenium (Ru), manganese (Mn), titanium (Ti), tantalum (Ta), aluminum (Al), a combination thereof, or an alloy thereof, but the present inventive concept is not limited thereto.

As illustrated in FIGS. 2A and 2B, an upper surface of each of the plurality of source/drain contacts CA, the insulating liner 142, and the inter-gate insulating layer 144 may be covered by an upper insulating structure 180. The upper insulating structure 180 may include an etching stop layer 182 and an inter-layer insulating layer 184, which are sequentially stacked on each of the plurality of source/drain contacts CA, the insulating liner 142, and the inter-gate insulating layer 144. The etching stop layer 182 may include, for example, silicon carbide (SiC), SiN, nitrogen-doped silicon carbide (SiC: N), SiOC, AlN, AlON, AlO, AlOC, or a combining thereof. The inter-layer insulating layer 184 may include an, for example, oxide layer, a nitride layer, an ultra low k (ULK) layer having an ultra low dielectric constant K of about 2.2 to about 2.4, or a combination thereof. For example, the inter-layer insulating layer 184 may include a tetra-ethyl-ortho-silicate (TEOS) layer, a high density plasma (HDP) layer, a boro-phospho-silicate glass (BPSG) layer, a flowable chemical vapor deposition (FCVD) oxide layer, an SiON layer, an SiOC layer, an SiCOH layer, or a combination thereof, but the present inventive concept is not limited thereto.

As illustrated in FIGS. 2A and 2B, a plurality of source/drain via contacts VA may be respectively arranged on the plurality of source/drain contacts CA. Each of the plurality of source/drain via contacts VA may penetrate the upper insulating structure 180 and be in contact with the source/drain contact CA. Each of the plurality of source/drain areas 130 may be electrically connected to the source/drain via contact VA via the metal silicide layer 172 and the source/drain contact CA. For example, a lower surface of each of the plurality of source/drain via contacts VA may be in contact with an upper surface of the source/drain contact CA. For example, each of the plurality of source/drain via contacts VA may include Mo or W, but the present inventive concept is not limited thereto.

As illustrated in FIG. 2A, a power pad PP and a ground pad GP may be arranged under the second surface 102_2 of the substrate 102. The power pad PP and the ground pad GP may be arranged under a backside insulating layer 101 that is arranged under the second surface 102_2 of the substrate 102. For example, the backside insulating layer 101 may include silicon oxide. In embodiments of the present inventive concept, a current may flow through the integrated circuit device 100 via the power pad PP. The integrated circuit device 100 may be grounded via the ground pad GP.

As illustrated in FIG. 2A, the integrated circuit device 100 may include a first through electrode 150_1 and a second through electrode 150_2, which penetrate the backside insulating layer 101 and extend in the vertical direction (Z direction). The integrated circuit device 100 may include a first wiring line M1, a second wiring line M2, and a third wiring line M3, which are arranged above the first surface 102_1 of the substrate 102. The integrated circuit device 100 may include a plurality of wiring contacts MC for mediating electrical connections between the first wiring line M1, the second wiring line M2, and the third wiring line M3.

For example, the first wiring line M1 may be connected to the power pad PP via the first through electrode 150_1. The second wiring line M2 may be connected to the ground pad GP via the second through electrode 150_2. The third wiring line M3 may be connected to the first wiring line M1 and the second wiring line M2 via the wiring contact MC.

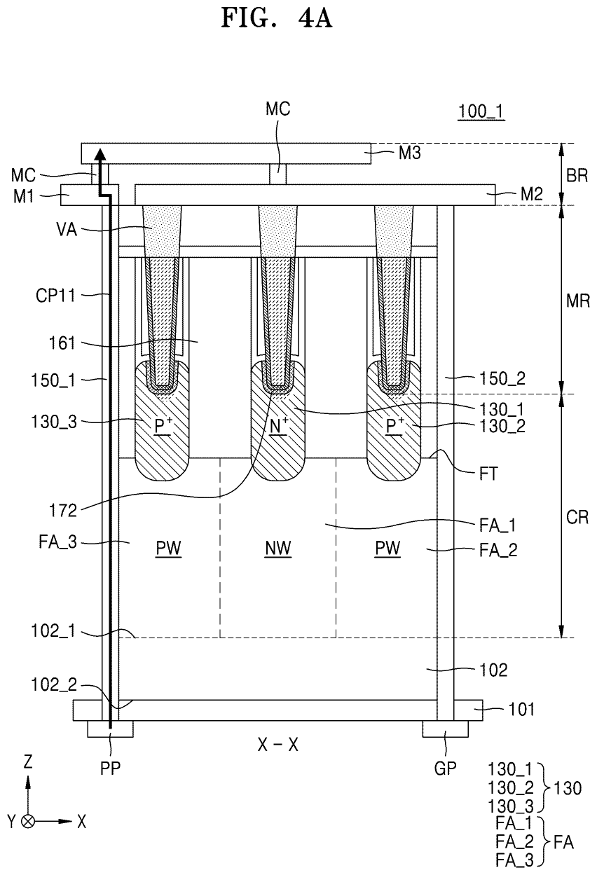

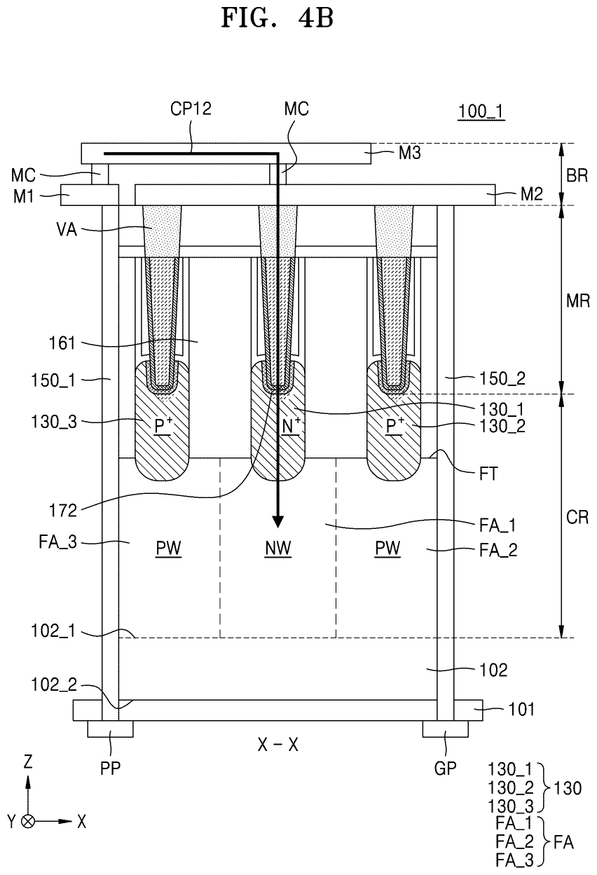

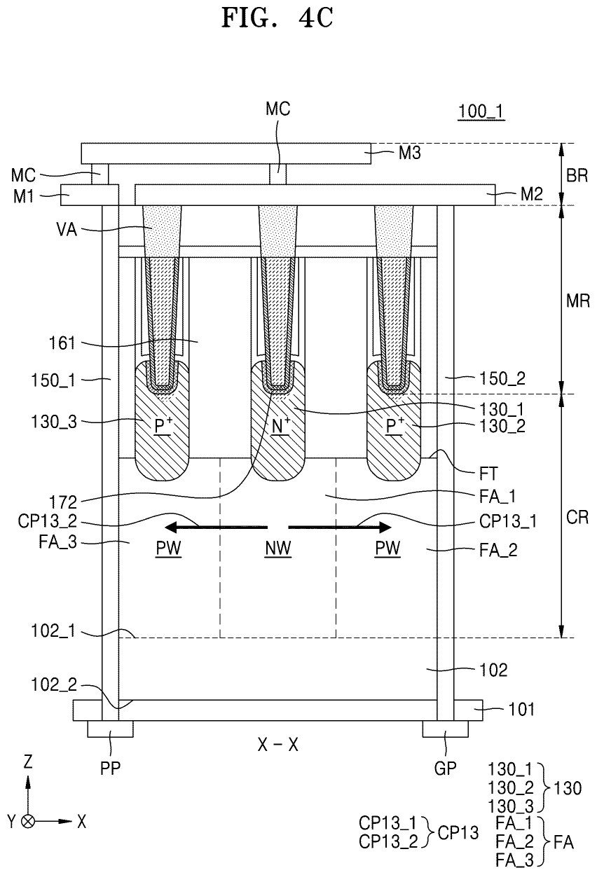

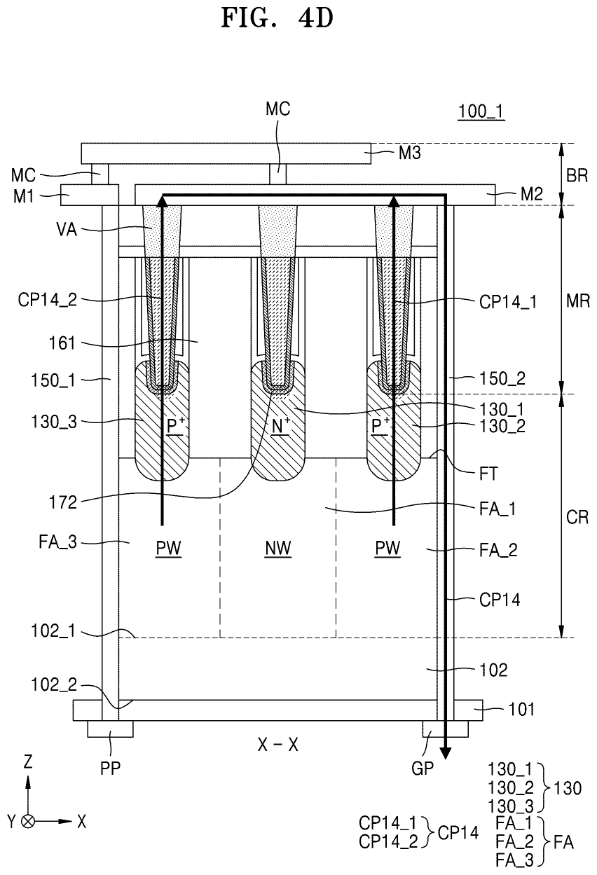

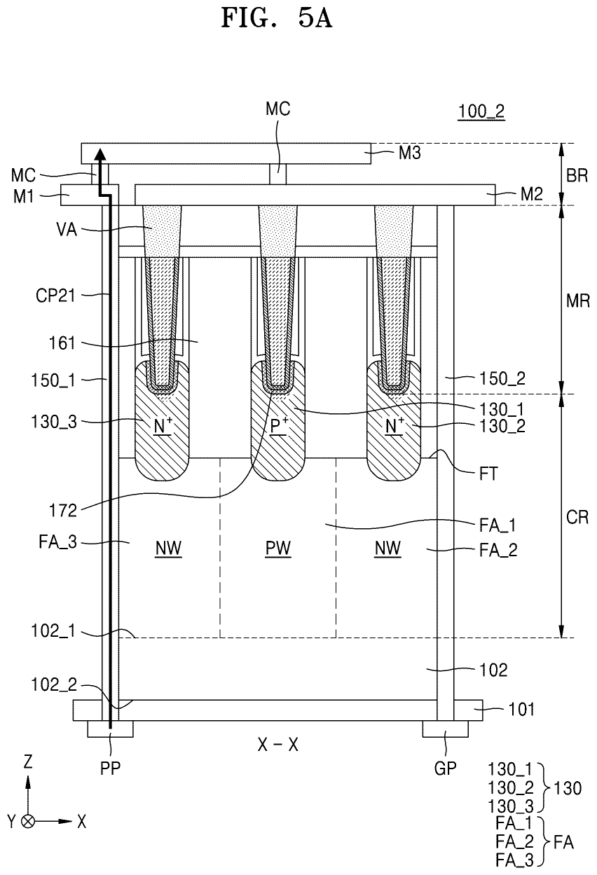

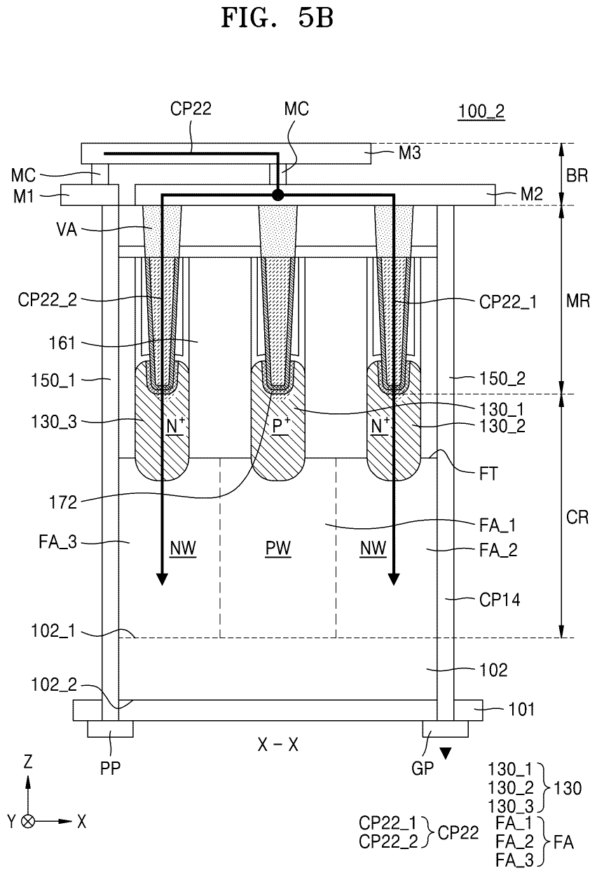

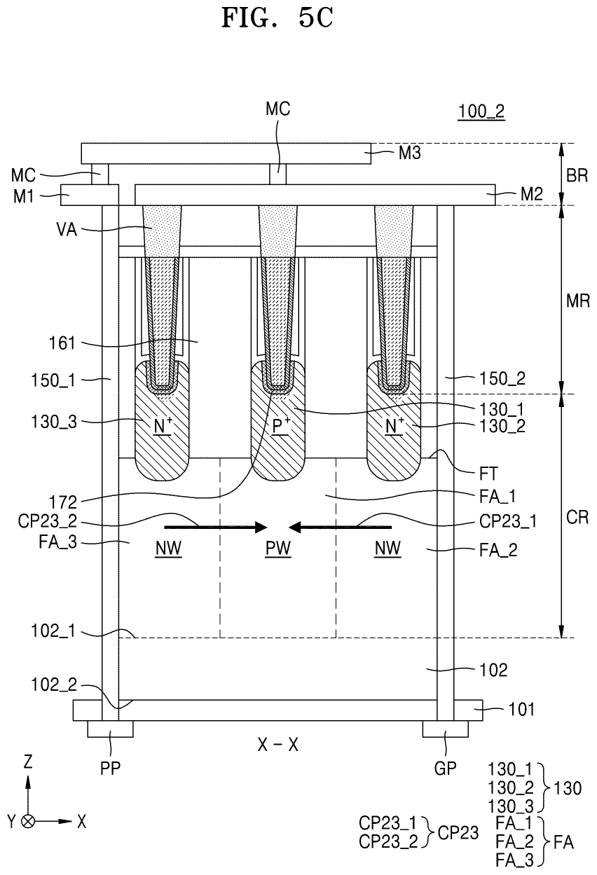

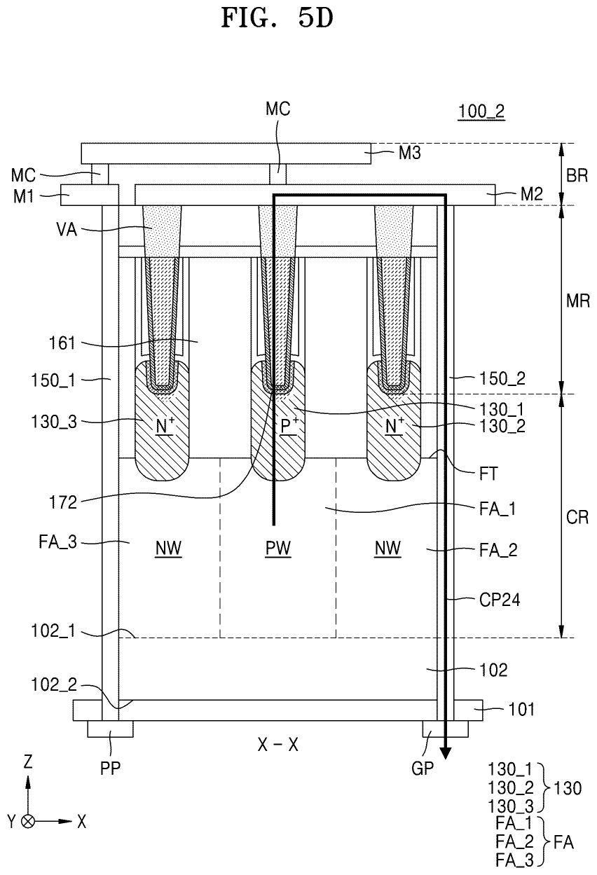

The integrated circuit device 100 described with reference to FIGS. 1, 2A, and 2B may include an electrostatic discharge (ESD) diode element. In other words, when the static electricity occurs, a current may flow through the integrated circuit device 100 via the power pad PP, and the current may be discharged via the ground pad GP. A current path in the integrated circuit device 100 is described in detail with reference to FIGS. 4A through 4D and 5A through 5D.

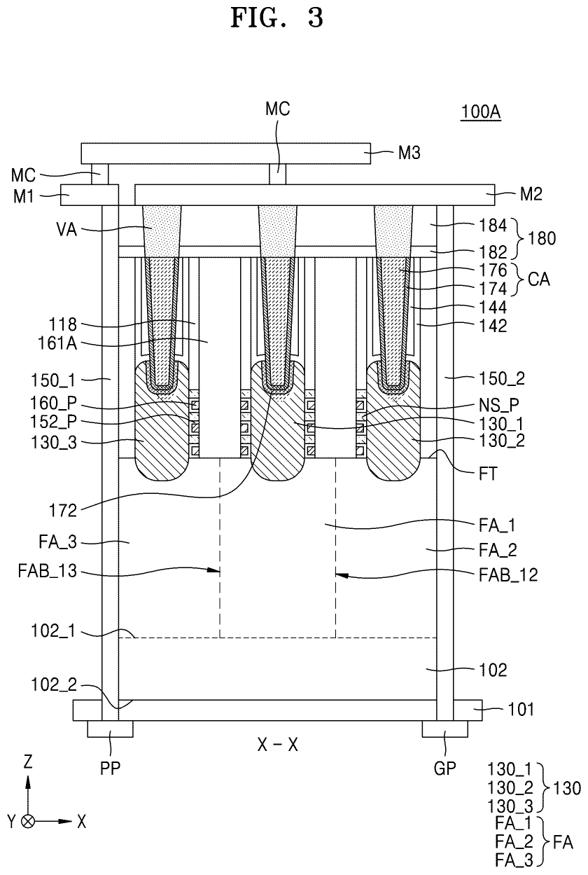

FIG. 3 is a cross-sectional view of an integrated circuit device 100A according to an embodiment of the present inventive concept. Differences from the integrated circuit device 100 described with reference to FIGS. 1, 2A, and 2B are mainly described.

Referring to FIG. 3, the integrated circuit device 100A may include a plurality of gate portions 160_P, a plurality of gate dielectric layer portions 152_P, a plurality of nanosheet portions NS_P, and/or a plurality of outer insulating spacers 118. The integrated circuit device 100A may include the gate portion 160_P, the gate dielectric layer portion 152_P, the nanosheet portion NS_P, and/or the outer insulating spacer 118 arranged between each of the plurality of source/drain areas 130 and the filling insulating layer 161. For example, the gate portion 160_P, the gate dielectric layer portion 152_P, the nanosheet portion NS_P, and the outer insulating spacer 118 may be arranged between the first source/drain area 130_1 and the filling insulating layer 161A, between the second source/drain area 130_2 and the filling insulating layer 161A, and/or between the third source/drain area 130_3 and the filling insulating layer 161A. For example, the gate dielectric layer portion 152_P may be arranged between the gate portion 160_P and the nanosheet portion NS_P.

In embodiments of the present inventive concept, a plurality of gate portions 160_P and the plurality of nanosheet portions NS_P may be alternately arranged on the fin upper surface FT of the fin-type active area FA. For example, each of the plurality of gate portions 160_P may be arranged between the fin-type active area FA and the lowermost nanosheet portion NS_P and/or between each of the plurality of nanosheet portions NS_P. For example, each of the plurality of nanosheet portions NS_P may be arranged between each of the plurality of gate portions 160_P and/or between the uppermost gate portion 160_P and the outer insulating spacer 118. In embodiments of the present inventive concept, the outer insulating spacer 118 may be arranged on the plurality of gate portions 160_P, the gate dielectric layer portion 152_P, and the plurality of nanosheet portions NS_P.

FIGS. 4A and 4D are cross-sectional views of an integrated circuit device 100_1 according to embodiments of the present inventive concept. FIGS. 4A through 4D are cross-sectional views for describing current paths in the integrated circuit device 100_1.

As illustrated in FIGS. 4A through 4D, the integrated circuit device 100_1 may include the first area FA_1 and the first source/drain area 130_1, which are doped with an N-type, and may include the second area FA_2, the third area FA_3, the second source/drain area 130_2, and the third source/drain area 130_3, which are doped with a P-type.

For example, the first area FA_1 may be doped with an N well or an N-type, and the first source/drain area 130_1 may be doped with an N⁺ type. In other words, the first source/drain area 130_1 may include an N-type having greater concentration than a concentration of the first area FA_1. For example, the second area FA_2 may be doped with a P well or a P-type, and the second source/drain area 130_2 may be doped with a P⁺ type. In other words, the second source/drain area 130_2 may include a P type having greater concentration than a concentration of the second area FA_2. For example, the third area FA_3 may be doped with a P well area or a P-type, and the third source/drain area 130_3 may be doped with a P⁺ type. In other words, the third source/drain area 130_3 may include a P type conductivity type having greater concentration than a concentration of the third area FA_3.

Referring to FIG. 4A, a voltage may be applied to the power pad PP. As a voltage is applied to the power pad PP, a current may flow to a back end line area BR via the first through electrode 150_1. For example, a current may sequentially pass through the first through electrode 150_1, the first wiring line M1, and the wiring contact MC, and may flow to the third wiring line M3. In other words, a first current path CP11 may be formed through the first through electrode 150_1 in the vertical direction (Z direction).

Referring to FIG. 4B, a current may flow from the first source/drain area 130_1 to the first area FA_1. For example, from the third wiring line M3, a current may sequentially flow through the wiring contact MC, the second wiring line M2, the source/drain via contact VA, and the source/drain contact CA, and into a middle end line area MR, that is, the first source/drain area 130_1. Next, a current may flow from the first source/drain area 130_1 to a channel area CR, that is, the first area FA_1. In other words, a second current path CP12 following from the first current path CP11 may be formed through the first source/drain area 130_1 to the first area FA_1 in the vertical direction (Z direction).

Referring to FIG. 4C, a current may flow from the first area FA_1 to the second area FA_2, that is, CP13_1, and/or from the first area FA_1 to the third area FA_3, that is, CP13_2. In other words, a third current path CP13 following from the second current path CP12 may include a current path formed from the first area FA_1 to the second area FA_2 and/or the third area FA_3 in the first horizontal direction (X direction).

Referring to FIG. 4D, a current may flow from the second area FA_2 to the ground pad GP via the second source/drain area 130_2, and/or a current may flow from the third area FA_3 to the ground pad GP via the third source/drain area 130_3. For example, a current may flow from the second area FA_2 through the second source/drain area 130_2, the source/drain contact CA, and the source/drain via contact VA to the second wiring line M2, which may collectively form a first flow line CP14_1, and then, may flow through the second through electrode 150_2 to the ground pad GP. The current may flow through the ground pad GP to the outside of the integrated circuit device 100_1. Similarly, a current may flow from the third area FA_3 through the third source/drain area 130_3, the source/drain contact CA, and the source/drain via contact VA to the second wiring line M2, which may collectively form a second flow line CP14_2, and then, may flow through the second through electrode 150_2 to the ground pad GP. In other words, a current may flow from the channel area CR through the middle end line area MR to the back end line area BR, and may flow outside the integrated circuit device 100_1. In other words, the fourth current path CP14, which follows the third current path CP13, may include a current path formed from the second area FA_2 to the second source/drain area 130_2 and/or the third area FA_3 to the third source/drain area 130_3, and a current path formed through the second through electrode 150_2 in the vertical direction (Z direction).

The current flows inside the integrated circuit device 100_1 have been described with reference to FIGS. 4A through 4D. As described above, the integrated circuit device 100_1 may include an ESD element, and accordingly, the voltage applied to the power pad PP may include an abnormal current, that is, a static electricity. In other words, when the static electricity is generated, through the current path described with reference to FIGS. 4A through 4D, the static electricity may be discharged via the ground pad GP.

FIGS. 5A and 5D are cross-sectional views of an integrated circuit device 100_2 according to embodiments of the present inventive concept. FIGS. 5A through 5D are cross-sectional views for describing current paths in the integrated circuit device 100_2.

As illustrated in FIGS. 5A through 5D, the integrated circuit device 100_2 may include the first area FA_1 and the first source/drain area 130_1, which are doped with a P type, and may include the second area FA_2, the third area FA_3, the second source/drain area 130_2, and the third source/drain area 130_3, which are doped with an N type.

For example, the first area FA_1 may be doped with a P well or a P-type, and the first source/drain area 130_1 may be doped with a P⁺ type. In other words, the first source/drain area 130_1 may include a P-type having greater concentration than a concentration of the first area FA_1. For example, the second area FA_2 may be doped with an N well or an N-type, and the second source/drain area 130_2 may be doped with an N⁺ type. In other words, the second source/drain area 130_2 may include an N-type having greater concentration than a concentration of the second area FA_2. For example, the third area FA_3 may be doped with an N well or an N-type, and the third source/drain area 130_3 may be doped with an N⁺ type. In other words, the third source/drain area 130_3 may include an N-type having greater concentration than a concentration of the third area FA_3.

Referring to FIG. 5A, a voltage may be applied to the power pad PP. As a voltage is applied to the power pad PP, a current may flow to a back end line area BR via the first through electrode 150_1. For example, a current may sequentially pass through the first through electrode 150_1, the first wiring line M1, and the wiring contact MC, and may flow to the third wiring line M3. In other words, a first current path CP21 may be formed through the first through electrode 150_1 in the vertical direction (Z direction).

Referring to FIG. 5B, a current may flow from the second source/drain area 130_2 to the second area FA_2 and/or from the third source/drain area 130_3 to the third area FA_3. For example, a current may flow from the third wiring line M3 and sequentially through the wiring contact MC, the second wiring line M2, the source/drain via contact VA, and the source/drain contact CA, and into a middle end line area MR, that is, the second source/drain area 130_2 and/or the third source/drain area 130_3. Next, a current may flow from the second source/drain area 130_2 to the channel area CR, that is, the second area FA_2, and/or the current may flow from the third source/drain area 130_3 to the third area FA_3. For example, the current may flow through a first flow line CP22_1, which may be provided by the second source/drain area 130_2 and the second area FA_2, and/or the current may flow through a second flow line CP22_2, which may be provided by the third source/drain area 130_3 and the third area FA_3. In other words, a second current path CP22, which follows the first current path CP21, may include a current path formed from the second source/drain area 130_2 to the second area FA_2, and/or a current path formed from the third source/drain area 130_3 to the third area FA_3 in the vertical direction (Z direction).

Referring to FIG. 5C, a current may flow from the second area FA_2 to the first area FA_1, and/or from the third area FA_3 to the first area FA_1. For example, the current may flow through a first flow line CP23_1, which may be provided by the second area FA_2 and the first area FA_1, and/or the current may flow through a second flow line CP23_2, which may be provided by the third area FA_3 and the first area FA_1. In other words, a third current path CP23, which follows the second current path CP22, may include a current path formed from the second area FA_2 to the first area FA_1 and/or a current path formed from the third area FA_3 to the first area FA_1 in the first horizontal direction (X direction).

Referring to FIG. 5D, a current may flow from the first area FA_1 through the first source/drain area 130_1 to the ground pad GP. For example, a current may flow from the first area FA_1 through the first source/drain area 130_1, the source/drain contact CA, and the source/drain via contact VA to the second wiring line M2, and then, may flow through the second through electrode 150_2 to the ground pad GP. The current may flow through the ground pad GP to the outside of the integrated circuit device 100_2. In other words, a current may flow from the channel area CR through the middle end line area MR to the back end line area BR, and may flow outside the integrated circuit device 100_1. In other words, a fourth current path CP24, which follows the third current path CP23, may include a current path that is formed from the first area FA_1 to the first source/drain area 130_1, and a current path that is formed through the second through electrode 150_2 in the vertical direction (Z direction).

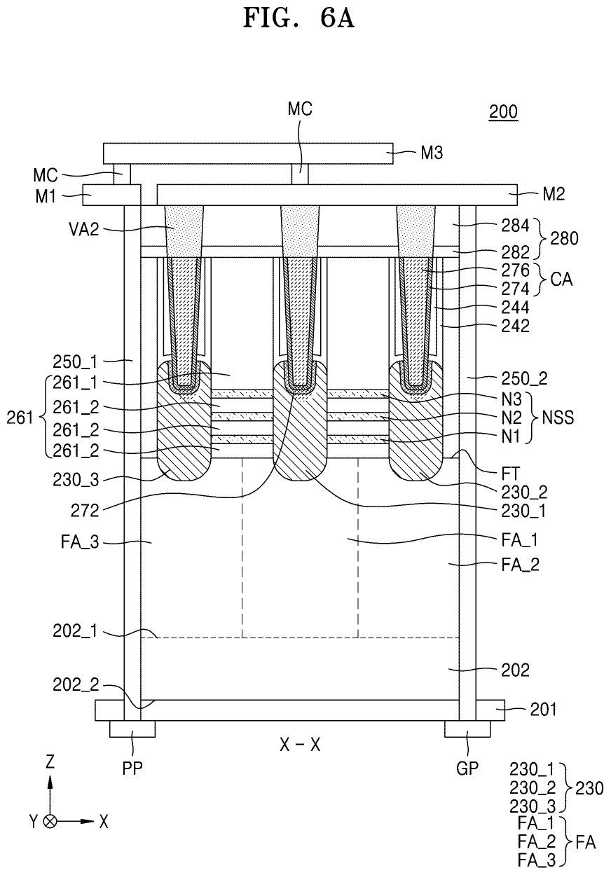

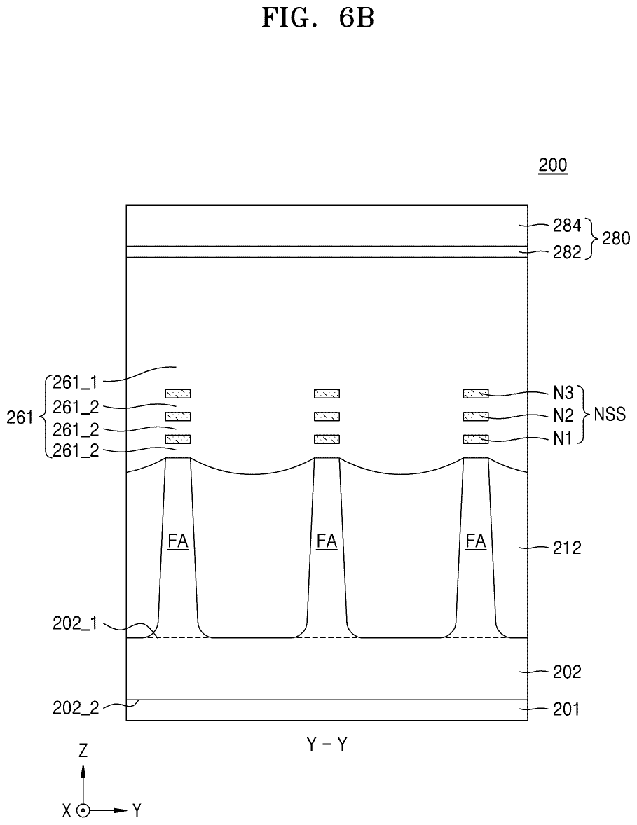

FIGS. 6A and 6B are cross-sectional views of example configurations of an integrated circuit device 200, according to embodiments of the present inventive concept. FIG. 6A is a cross-sectional view taken along line X-X in FIG. 1. FIG. 6B is a cross-sectional view taken along line Y-Y in FIG. 1. Differences from the integrated circuit device 100 described with reference to FIGS. 1, 2A, and 2B are mainly described.

Referring to FIGS. 6A and 6B, the integrated circuit device 200 may further include a plurality of nanosheet stacks NSS, which are in contact with the plurality of source/drain areas 230, between each of the plurality of source/drain areas 230. The plurality of source/drain areas 230 may be connected to the wiring lines M1, M2, and M3 via the source/drain contact CA, which penetrates an insulating liner 242 and an inter-gate insulating layer 244, and the source/drain via contact VA2, which penetrates an upper insulating structure 280. The upper insulating structure 280 may include an etching stop layer 282 and an interlayer insulating layer 284. A backside insulating layer 201 may be arranged on a second surface 202_2 of a substrate 202.

The plurality of nanosheet stacks NSS may be disposed on the fin top surface FT of each of the plurality of fin-type active areas FA in areas where the plurality of fin-type active areas FA and a plurality of filling insulating layers 261 cross each other. Each of the plurality of nanosheet stacks NSS may include at least one nanosheet facing the fin upper surface FT that is spaced apart from the fin upper surface FT of the fin-type active area FA in the vertical direction (Z direction). The term “nanosheet” used in the present inventive concept may be referred to as a conductive structure having a cross-section substantially perpendicular to a direction in which a current flows. The nanosheet should be understood to include nanowires.

As illustrated in FIGS. 6A and 6B, each of the plurality of nanosheet stacks NSS may include a first nanosheet N1, a second nanosheet N2, and a third nanosheet N3, which overlap each other on the fin-type active area FA in the vertical direction (Z direction). Vertical distances (Z direction distance) of the first nanosheet N1, the second nanosheet N2, and the third nanosheet N3 from the fin upper surface FT of the fin-type active area FA may be different from each other. Each of the plurality of filling insulating layers 261 may surround the first nanosheet N1, the second nanosheet N2, and the third nanosheet N3, which overlap each other.

In this example, a configuration is illustrated in which the plurality of nanosheet stacks NSS and the plurality of filling insulating layers 261 are formed on one fin-type active area FA, and the plurality of nanosheet stacks NSS are arranged on one fin-type active area FA in a line in the first horizontal direction (X direction). However, the number of each of the nanosheet stacks NSS and the filling insulating layers 261, which are arranged above one fin-type active area FA is not particularly limited.

As illustrated in FIG. 6A, the first nanosheet N1, the second nanosheet N2, and the third nanosheet N3, which are included in one nanosheet stack NSS, may have the same size as or similar sizes to each other in the first horizontal direction (X direction). In embodiments of the present inventive concept, unlike as illustrated in FIG. 6A, at least some of the first nanosheet N1, the second nanosheet N2, and the third nanosheet N3, which are included in one nanosheet stack NSS, may have different sizes from each other in the first horizontal direction (X direction). In this example, the case where each of the plurality of nanosheet stacks NSS respectively includes three nanosheets is an example, but the present inventive concept is not limited thereto. For example, the nanosheet stack NSS may include at least one nanosheet, and the number of nanosheets constituting the nanosheet stack NSS is not particularly limited.

As illustrated in FIGS. 6A and 6B, each of the plurality of filling insulating layers 261 may include a first filling insulating layer 261_1 and a plurality of second filling insulating layer 261_2. The first filling insulating layer 261_1 may cover an upper surface of the nanosheet stack NSS, and extend in the second horizontal direction (Y direction). The plurality of second filling insulating layer 261_2 may be connected to the first filling insulating layer 261_1 in one body, and each of the plurality of second filling insulating layer 261_2 may be arranged between each of the first nanosheet N1, the second nanosheet N2, and the third nanosheet N3, and between the first nanosheet N1 and the fin-type active area FA. In the vertical direction (Z direction), a thickness of each of the plurality of second filling insulating layer 261_2 may be less than a thickness of the first filling insulating layer 261_1.

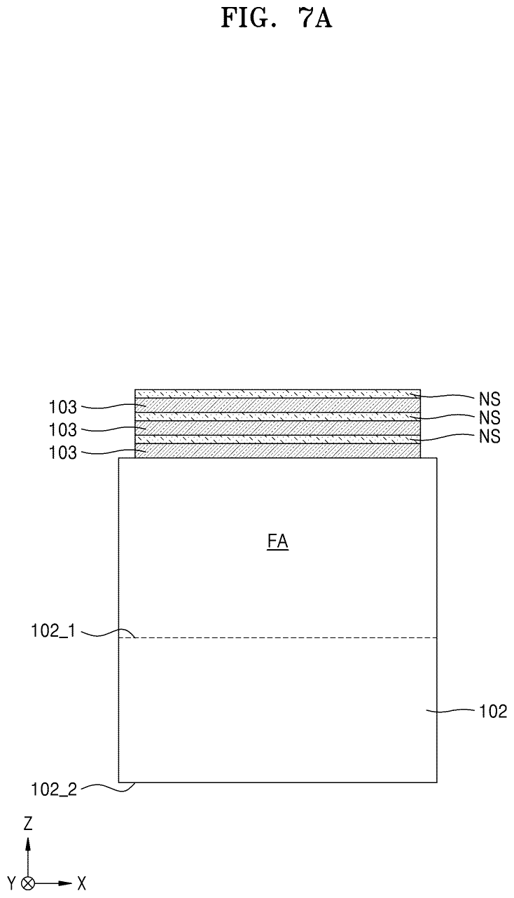

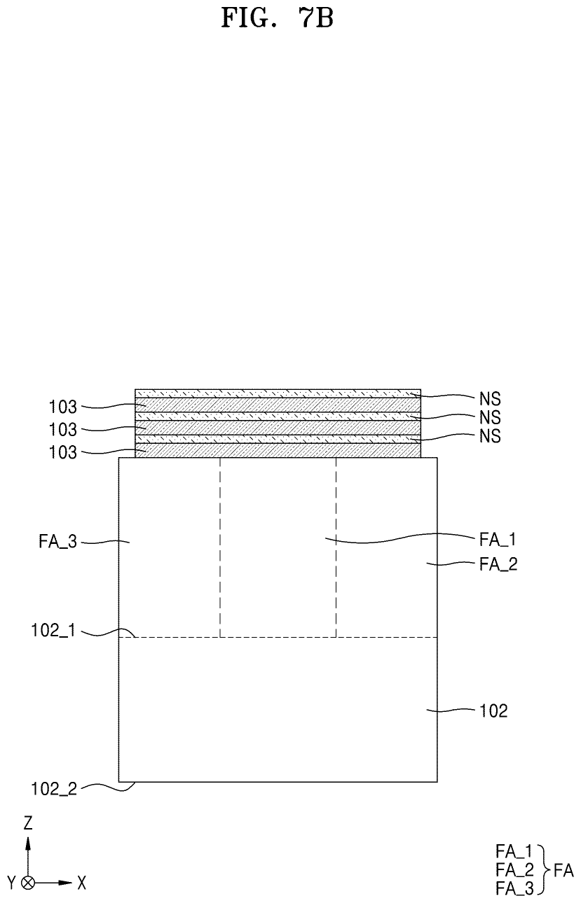

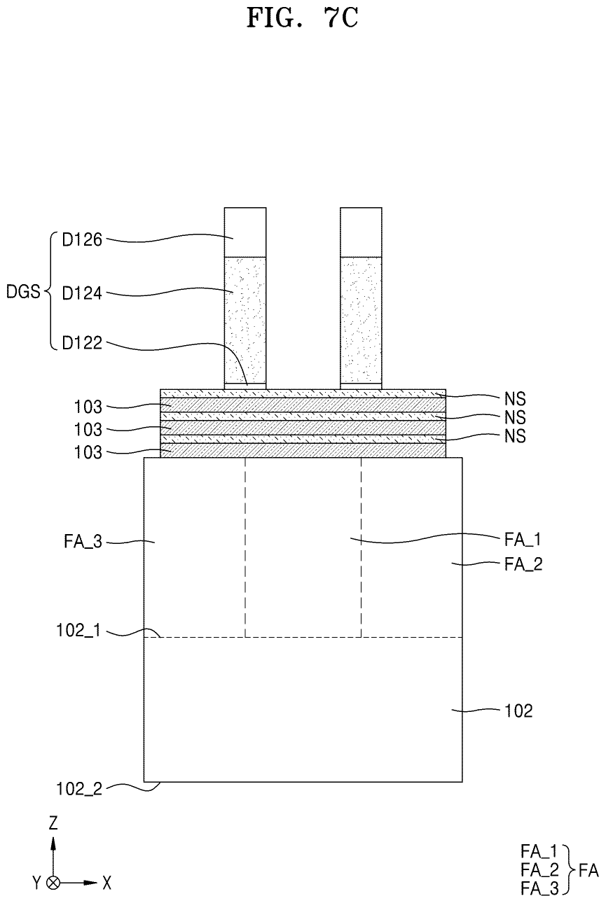

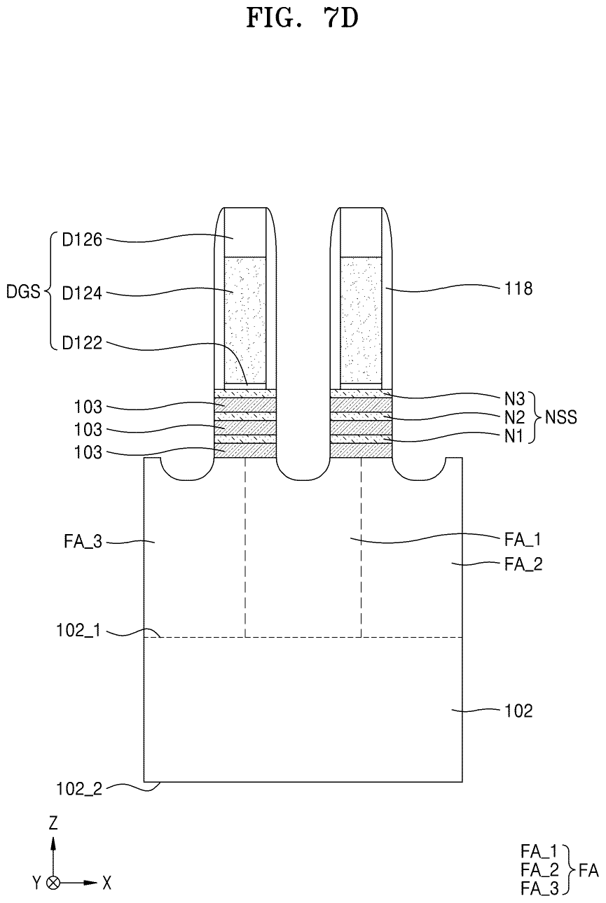

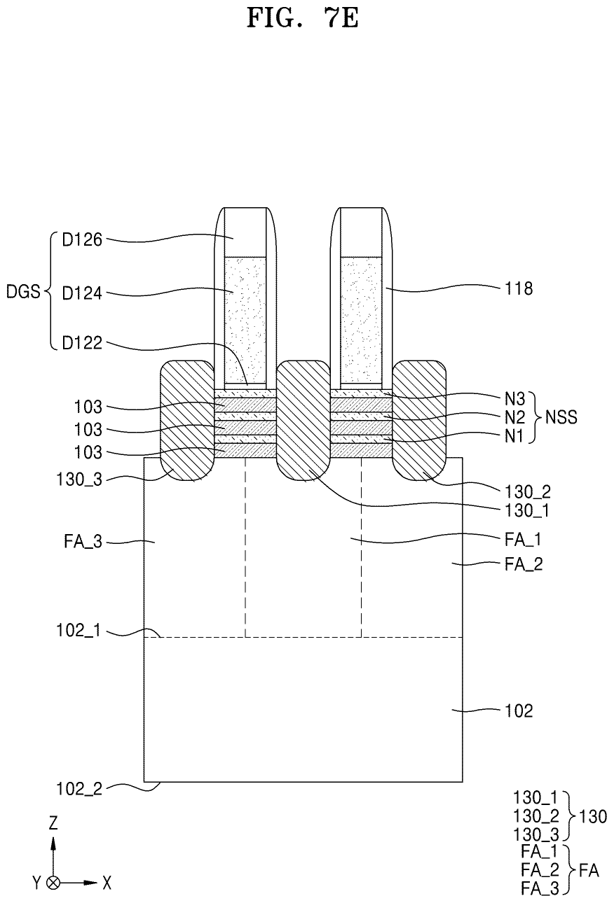

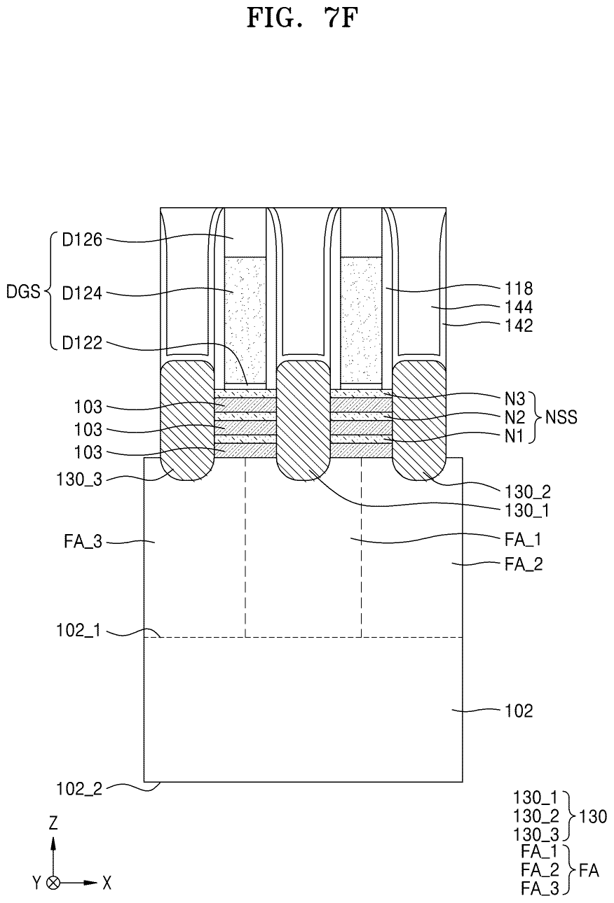

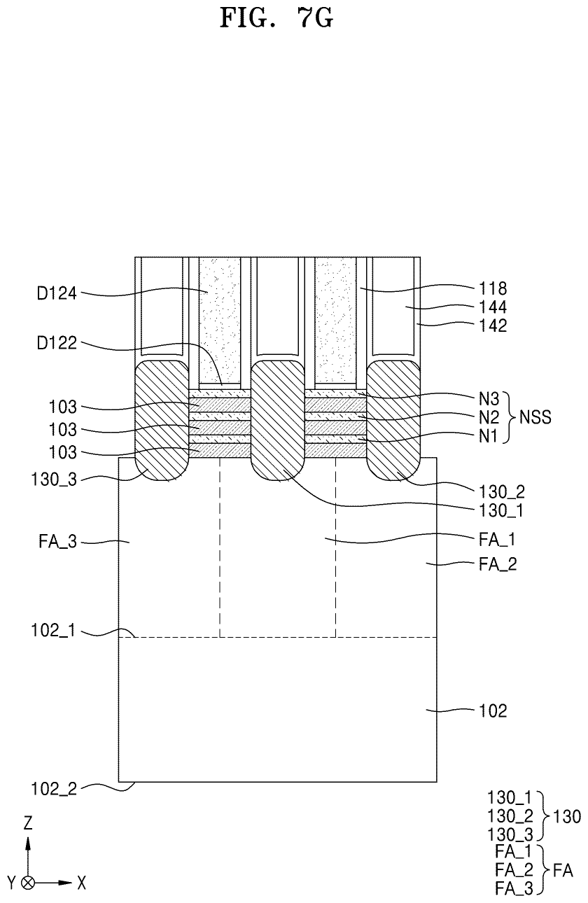

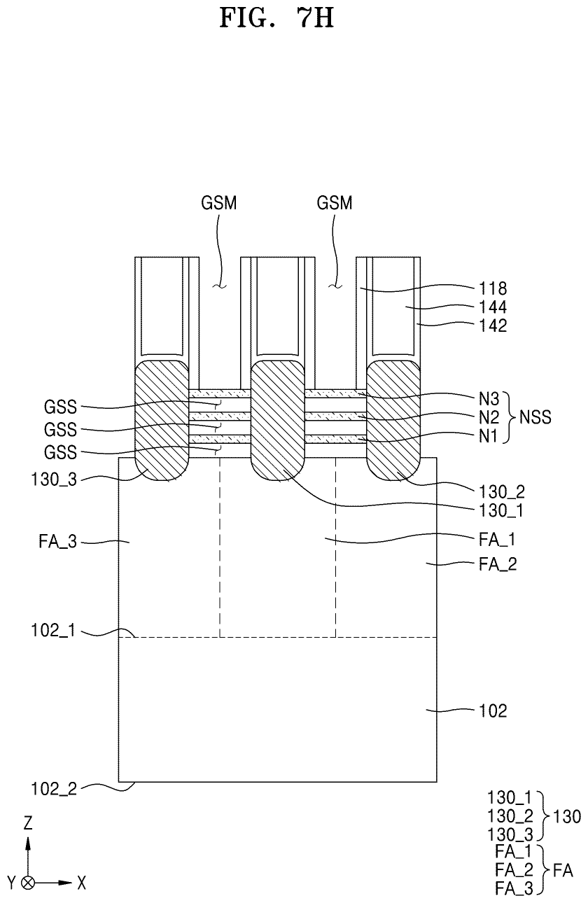

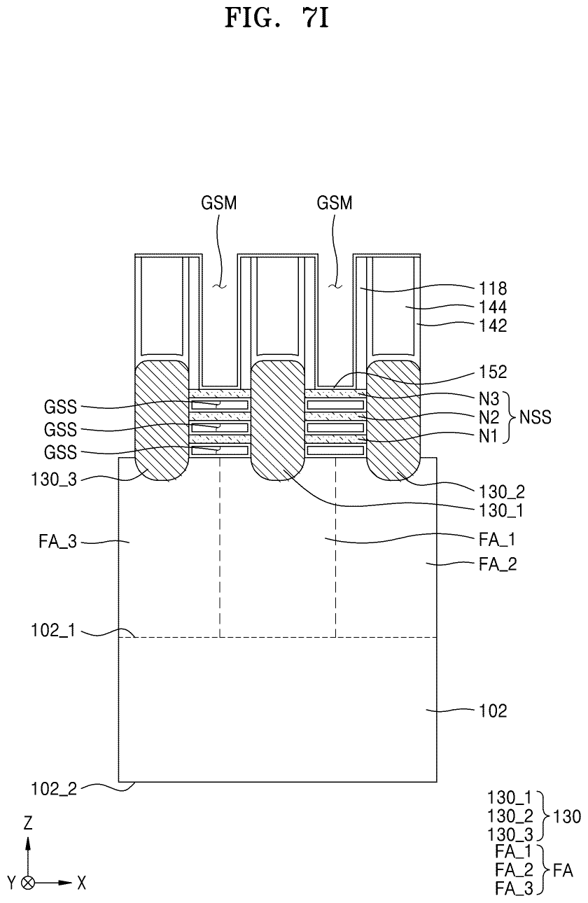

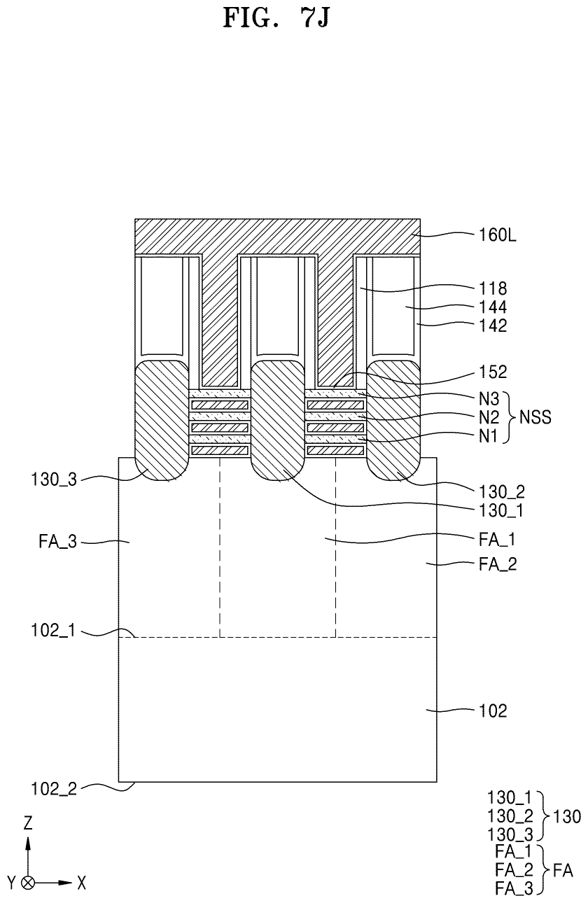

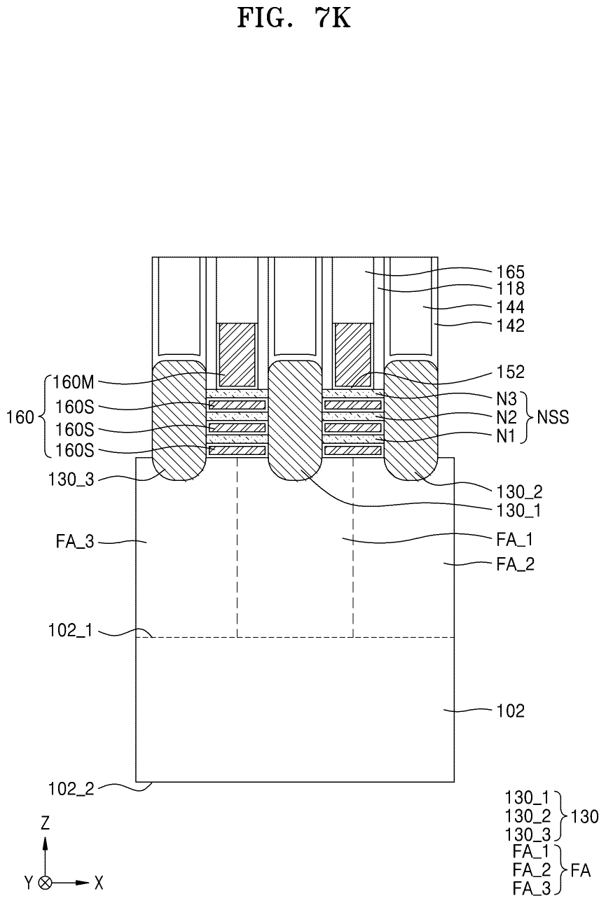

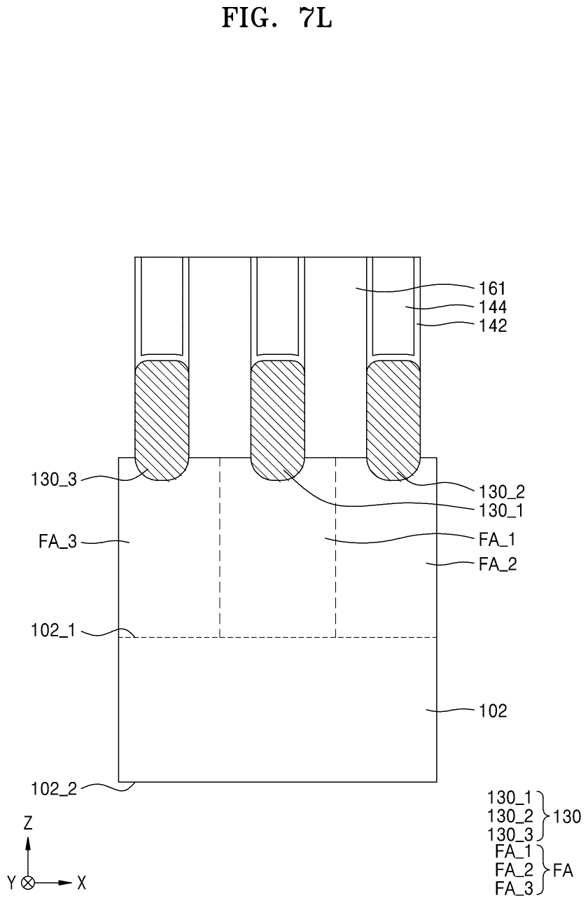

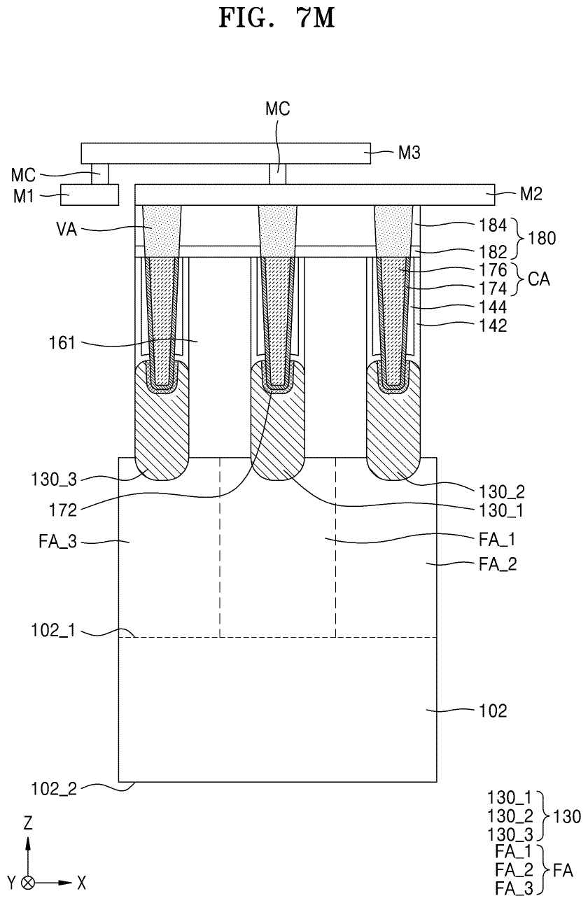

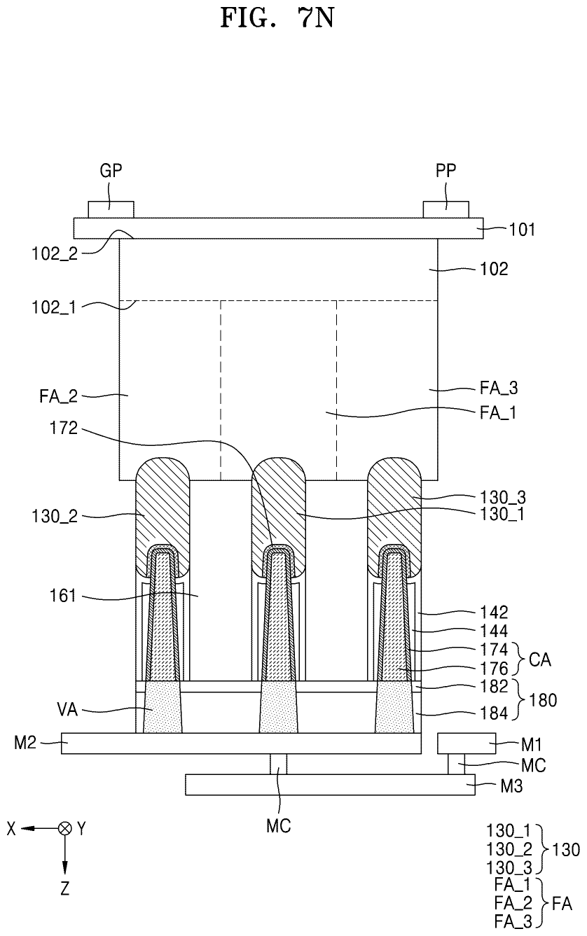

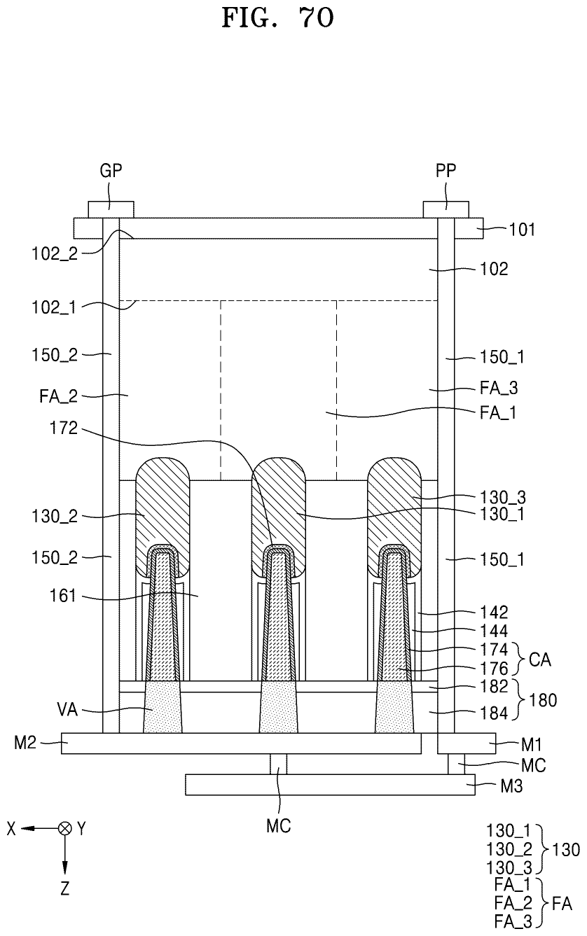

FIGS. 7A through 7O are cross-sectional views illustrating a method of manufacturing the integrated circuit device 100 according to embodiments of the present inventive concept. FIG. 7A through 7O are cross-sectional views taken along line X-X in FIG. 1.

Referring to FIG. 7A, a plurality of sacrificial semiconductor layers 103 and a plurality of nanosheet semiconductor layers NS may be alternately stacked on the substrate 102. In embodiments of the present inventive concept, the fin-type active area FA of the substrate 102 may be doped with a second conductivity type. For example, the fin-type active area FA may be doped with a second conductivity type at low concentration. In an embodiment of the present inventive concept, the fin-type active area FA may include a P well area. In embodiments of the present inventive concept, the fin-type active area FA may include an N well area.

The plurality of sacrificial semiconductor layers 103 and the plurality of nanosheet semiconductor layers NS may include semiconductor materials having different etching selectivity from each other. In embodiments of the present inventive concept, the plurality of nanosheet semiconductor layers NS may include a Si layer, and the plurality of sacrificial semiconductor layers 103 may include a SiGe layer. In embodiments of the present inventive concept, the Ge content in the plurality of sacrificial semiconductor layers 103 may be substantially constant. The SiGe layer constituting the plurality of sacrificial semiconductor layers 103 may have a substantially constant Ge content that is in the range of about 5 atomic percentage (atom %) to about 60 atom %, for example, about 10 atom % to about 40 atom %. The Ge content in the SiGe layer constituting the plurality of sacrificial semiconductor layers 103 may be variously selected as necessary.

Referring to FIG. 7B, the first area FA_1, the second area FA_2, and the third area FA_3 may be formed by performing a doping process of a first conductivity type that is different from the second conductivity type on a partial area of the fin-type active area FA. The doping process of the first conductivity type may be performed at a concentration higher than a concentration of the existing second conductivity type. The remaining partial areas, on which the doping process of the first conductivity type has not been performed, may be spaced apart from each other with the first area FA_1 disposed therebetween. For example, the first area FA_1 including a first conductivity type and the second area FA_2 and the third area FA_3, which are spaced apart from each other with the first area FA_1 disposed therebetween and include a second conductivity type, may be formed.

Referring to FIG. 7C, a plurality of dummy gate structures DGS may be formed on a stacked structure of the plurality of sacrificial semiconductor layers 103 and a plurality of nanosheet semiconductor layers NS.

Each of the plurality of dummy gate structures DGS may be formed to extend in the second horizontal direction (Y direction). Each of the plurality of dummy gate structures DGS may have a structure in which an oxide layer D122, a dummy gate layer D124, and a capping layer D126 are sequentially stacked. In embodiments of the present inventive concept, the dummy gate layer D124 may include polysilicon, and the capping layer D126 may include a silicon nitride layer.

Referring to FIG. 7D, after the plurality of outer insulating spacers 118, which cover both sidewalls of each of the plurality of dummy gate structures DGS, are formed, portions of each of the plurality of sacrificial semiconductor layers 103 and the plurality of nanosheet semiconductor layers NS and a portion of the fin-type active area FA may be etched by using the plurality of dummy gate structures DGS and the plurality of outer insulating spacers 118 as etching masks. Further, the plurality of nanosheet semiconductor layers NS may be divided into the plurality of nanosheet stacks NSS, and a plurality of recesses may be formed on the upper portion of the fin-type active area FA. Each of the plurality of nanosheet stacks NSS may include the first nanosheet N1, the second nanosheet N2, and the third nanosheet N3. To form the plurality of recesses, an etching process may be performed by using a dry etching operation, a wet etching operation, or a combination thereof.

Referring to FIG. 7E, the plurality of first drain regions 130 may be formed inside each of the plurality of recesses. The first source/drain area 130_1 may be formed on the first area FA_1. For example, the first source/drain area 130_1, which has a first conductivity type, may be formed on the first area FA_1, which has a first conductivity type. The second source/drain area 130_2 may be formed on the second area FA_2. For example, the second source/drain area 130_2, which has a second conductivity type, may be formed on the second area FA_2, which has a second conductivity type. The third source/drain area 130_3 may be formed on the third area FA_3. For example, the third source/drain area 130_3, which has a second conductivity type, may be formed on the third area FA_3, which has a second conductivity type.

In embodiments of the present inventive concept, to form the plurality of source/drain regions 130, a semiconductor material may be epitaxially grown from the surface of the fin-type active region FA that is exposed on the bottom of the recess, the sidewalls of each of the first nanosheet N1, the second nanosheet N2, and the third nanosheet N3 that are included in the nanosheet stack NSS, and the sidewalls of each of the plurality of sacrificial semiconductor layers 103.

Referring to FIG. 7F, after the insulating liner 142 which covers the resultant product of FIG. 7E, in which the plurality of source/drain areas 130 are formed, is formed, and an inter-gate insulating layer 144 is formed on the insulating liner 142, the insulating liner 142 and the inter-gate insulating layer 144 may be planarized to expose the upper surface of the capping layer D126.

Referring to FIG. 7G, the capping layer D126 may be removed to expose the upper surface of the dummy gate layer D124, and the insulating liner 142 and the inter-gate insulating layer 144 may be partially removed such that the upper surface of the insulating liner 142, the upper surface of the inter-gate insulating layer 144 and the upper surface of the dummy gate layer D124 are approximately on the same level as each other.

Referring to FIG. 7H, a dummy gate layer D124 and an oxide layer D122, which is disposed under the dummy gate layer D124, may be removed to prepare a main gate space GSM, and the plurality of nanosheet stacks NSS may be exposed through the main gate space GSM.

Next, the plurality of sacrificial semiconductor layers 103 that remain on the fin-type active area FA may be removed through the main gate space GSM to provide a sub-gate space GSS between each of the first nanosheet N1, the second nanosheet N2, and the third nanosheet N3 and between the first nanosheet N1 and the upper surface of the fin-type active area FA.

In embodiments of the present inventive concept, to selectively remove the plurality of sacrificial semiconductor layers 103, a difference in etching selectivity between the first nanosheet N1, the second nanosheet N2, and the third nanosheet N3, and the plurality of sacrificial semiconductor layers 103 may be used.

Referring to FIG. 7I, a gate dielectric layer 152 may be formed in the main gate space GSM and the sub-gate space GSS. The gate dielectric layer 152 that covers the exposed surface of the third nanosheet N3 may be formed in the main gate space GSM. The gate dielectric layer 152 covering the first through third nanosheets N1 through N3 may be formed in the sub-gate space GSS. An atomic layer deposition (ALD) process may be used for forming the gate dielectric layer 152.

Referring to FIG. 7J, a gate forming conductive layer 160L, which fills the main gate space GSM and the sub-gate space GSS and at the same time covers the upper surface of the inter-gate insulating layer 144, may be formed. For example, the gate forming conductive layer 160L may include a metal, a metal nitride, metal carbide, or a combination thereof. An ALD process or a CVD process may be used for forming the gate forming conductive layer 160L.

Referring to FIG. 7K, a portion of the gate forming conductive layer 160L may be removed from the upper surface thereof so that the upper surface of the insulating liner 142 and the upper surface of the inter-gate insulating layer 144 are exposed and a portion of the upper side of the main gate space (refer to GSM in FIG. 7J) is again emptied. As a result, a plurality of gate lines 160 may be formed from the gate forming conductive layer 160L. In this case, the gate dielectric layer 152 and the outer insulating spacer 118 may be partially consumed from the upper side of each of them in the main gate space GSM, so that the height of each of the gate dielectric layer 152 and the outer insulating spacer 118 may be lowered. Next, a capping insulating pattern 165, which fills the main gate space GSM, may be formed on the gate line 160.

Referring to FIG. 7L, the gate line 160 between the plurality of source/drain areas 130 may be removed, and by filling an insulating material in a space formed by the removed gate line 160, the filling insulating layer 161 extending in the second horizontal direction (Y direction) may be formed.

By using a non-selective etching process, the gate line 160, the gate dielectric layer 152, and the first through third nanosheets N1 through N3 between the plurality of source/drain areas 130 may be removed together. For example, by using a dry etching process, the gate line 160, the gate dielectric layer 152, and the first through third nanosheets N1 through N3 between the plurality of source/drain areas 130 may be removed. In this case, the capping insulating pattern 165 and the outer insulating spacer 118 on the gate line 160 may be removed together.

Referring to FIG. 7M, source/drain contact holes, which penetrate the insulating structure that includes the insulating liner 142 and the inter-gate insulating layer 144, and expose the source/drain area 130, may be formed. Thereafter, the metal silicide layer 172 may be formed on the exposed source/drain area 130, and the source/drain contact CA that includes the conductive barrier pattern 174 and the contact plug 176 may be formed on the metal silicide layer 172.

Next, the upper insulating structure 180 that includes the etching stop layer 182 and the inter-layer insulating layer 184 may be formed on the insulating liner 142, the inter-gate insulating layer 144, and the source/drain contact CA. Next, the plurality of source/drain via contacts VA, which penetrate the upper insulating structure 180, may be formed.

Next, the first wiring line M1, the second wiring line M2, and the third wiring line M3, which extend on the plurality of source/drain via contacts VA in the first horizontal direction (X direction), and a plurality of wiring contacts MC, which provide electrical connections between the first wiring line M1, the second wiring line M2, and the third wiring line M3, may be formed.

Referring to FIG. 7N, the resultant product of FIG. 7M may be turned over with respect to the vertical direction (Z direction). Thereafter, a portion of the substrate 102 may be removed. For example, a thinning operation may be performed on the substrate 102. For example, a grinding operation may be performed on the second surface 102_2 of the substrate 102.

Referring to FIG. 7N, the backside insulating layer 101 may be arranged on the second surface 102_2 of the substrate 102, and the first through electrode 150_1 and the second through electrode 150_2, which penetrate the backside insulating layer 101, may be formed. Next, the power pad PP, which is connected to the first through electrode 150_1, and the ground pad GP, which is connected to the second through electrode 150_2, may be formed to manufacture the integrated circuit device 100.

In other words, according to a method of manufacturing the integrated circuit device 100 according to embodiments of the present inventive concept described with reference to FIGS. 7A through 7O, the integrated circuit device 100, in which current flows between the first area FA_1 and the second area FA_2 and between the first area FA_1 and the third area FA_3 that are not cut even though a portion of the substrate 102 is removed, may be provided. In other words, the integrated circuit device 100 having improved static electricity performance and reliability may be provided.

An example method of manufacturing the integrated circuit device 100 illustrated in FIGS. 1, 2A, and 2B is described above with reference to FIGS. 7A through 7O, however, those of skill in the art should know that it is possible to manufacture integrated circuit devices 100A, 100_1, and 100_2 illustrated in FIGS. 3, 4A through 4D, and 5A through 5D, and integrated circuit devices that have various structures modified and changed therefrom, by applying various modifications and changes from descriptions given with reference to FIGS. 7A through 7O within the scope of the present inventive concept.

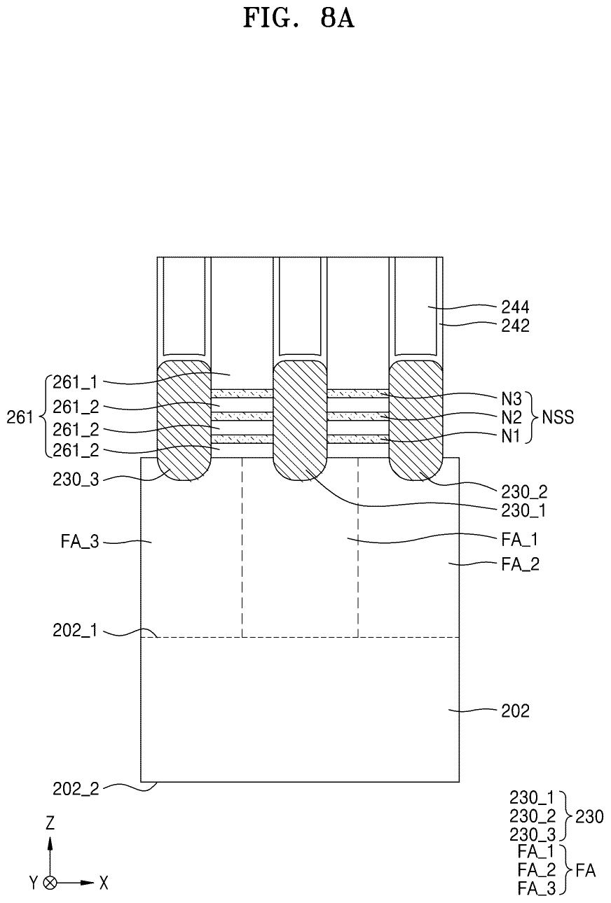

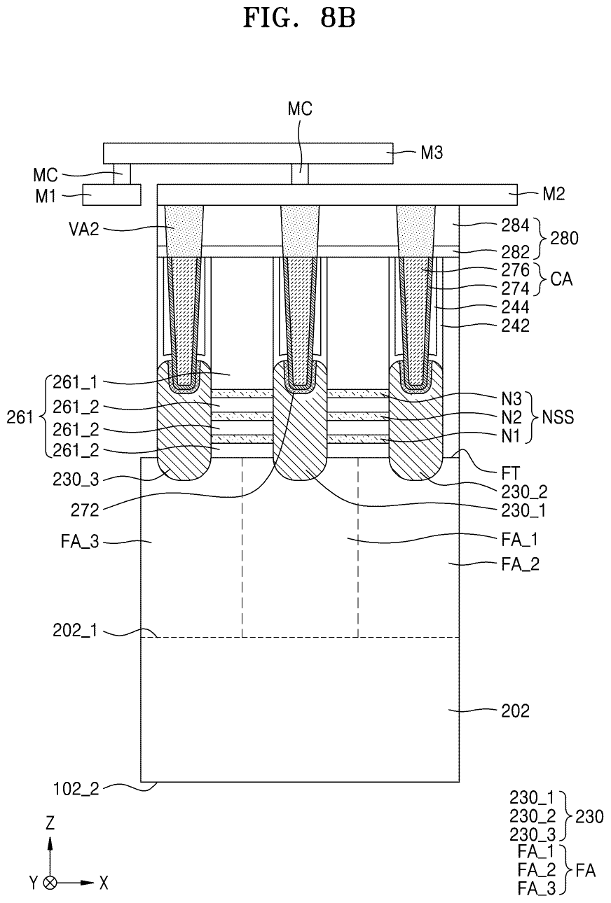

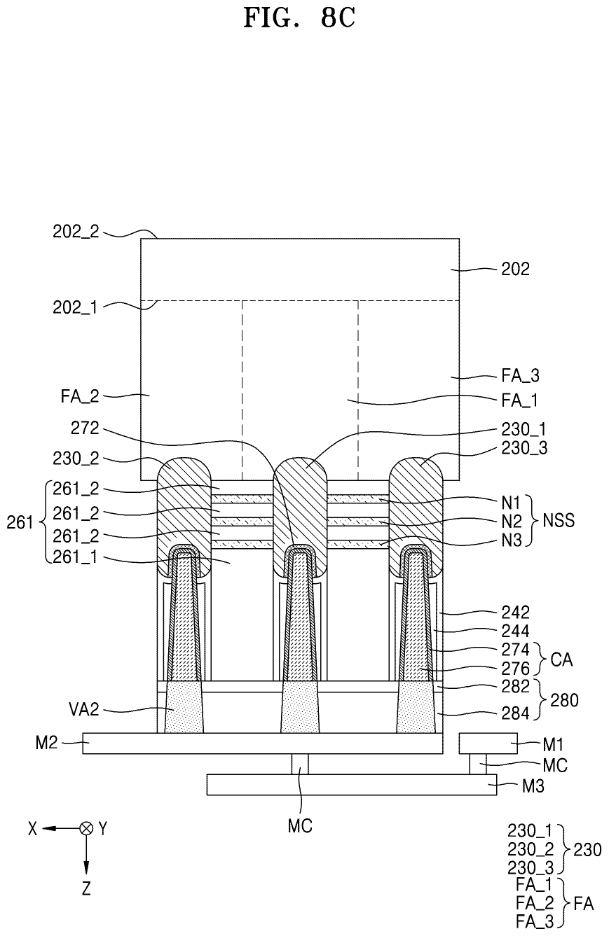

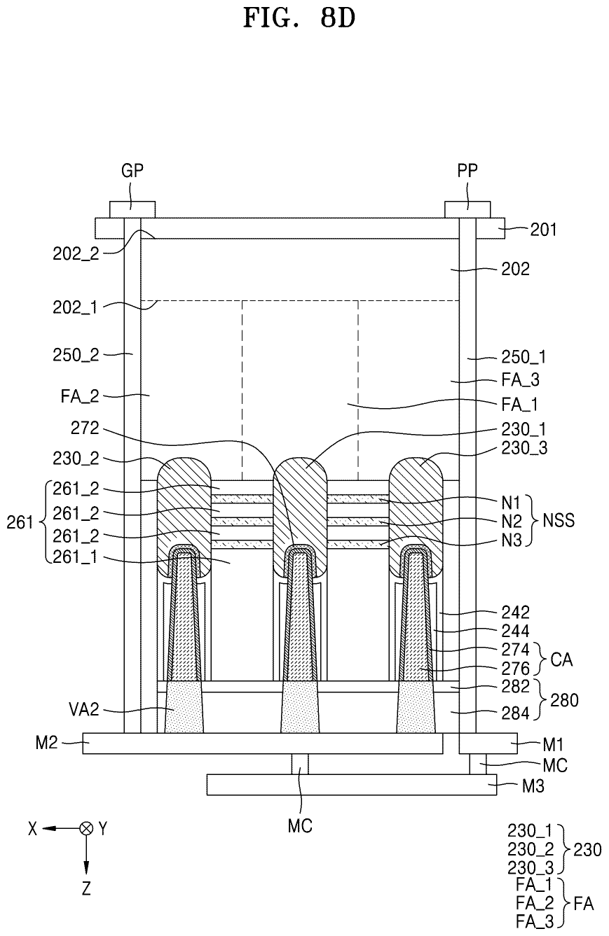

FIGS. 8A through 8D are cross-sectional views illustrating a method of manufacturing the integrated circuit device 200 according to embodiments of the present inventive concept. FIGS. 8A through 8D are cross-sectional views illustrating a method of manufacturing the integrated circuit device 200 according to a process sequence illustrating the method of manufacturing the integrated circuit device 200 subsequent to manufacturing operations described with reference to FIG. 7L. FIG. 8A through 8D are cross-sectional views taken along line X-X in FIG. 1.

Referring to FIG. 8A, a gate line 260 between the plurality of source/drain areas 230 may be removed, and the filling insulating layer 261 extending in the second horizontal direction (Y direction) may be formed by filling an insulating material in a space formed by the removal of gate line 260.

For example, the gate line 260 between the plurality of source/drain areas 230 may be removed by using a selective etching process. In this case, the first through third nanosheets N1 through N3 may remain without being removed due to a difference in etching selectivity from the gate line 260. In embodiments of the present inventive concept, a gate dielectric layer 252 and a capping insulating pattern 265 may be removed together.

Thereafter, by filling the removed space with an insulating material, the filling insulating layer 261, which extends in the second horizontal direction (Y direction) and surrounds the first nanosheet N1, the second nanosheet N2, and the third nanosheet N3, may be formed.

Referring to FIG. 8B, similarly to descriptions given with reference to FIG. 7M, the plurality of source/drain contacts CA and the plurality of source/drain via contacts VA may be formed. Next, the first wiring line M1, the second wiring line M2, and the third wiring line M3, which extend on the plurality of source/drain via contacts VA in the first horizontal direction (X direction), and a plurality of wiring contacts MC, which provide electrical connections between the first wiring line M1, the second wiring line M2, and the third wiring line M3 may be formed.

Referring to FIG. 8C, similarly to descriptions given with reference to FIG. 7N, the resultant product of FIG. 8B may be turned over with respect to the vertical direction (Z direction). Thereafter, a portion of the substrate 202 may be removed. For example, a grinding operation may be performed on the second surface 202_2 of the substrate 202.

Referring to FIG. 8D, similarly to descriptions given with reference to FIG. 7O, a first through electrode 250_1 and a second through electrode 250_2, which penetrate a silicon wafer 201 that is disposed on the second surface 202_2 of the substrate 202, may be formed. Next, the power pad PP, which is connected to the first through electrode 250_1, and the ground pad GP, which is connected to the second through electrode 250_2, may be formed to manufacture the integrated circuit device 200.

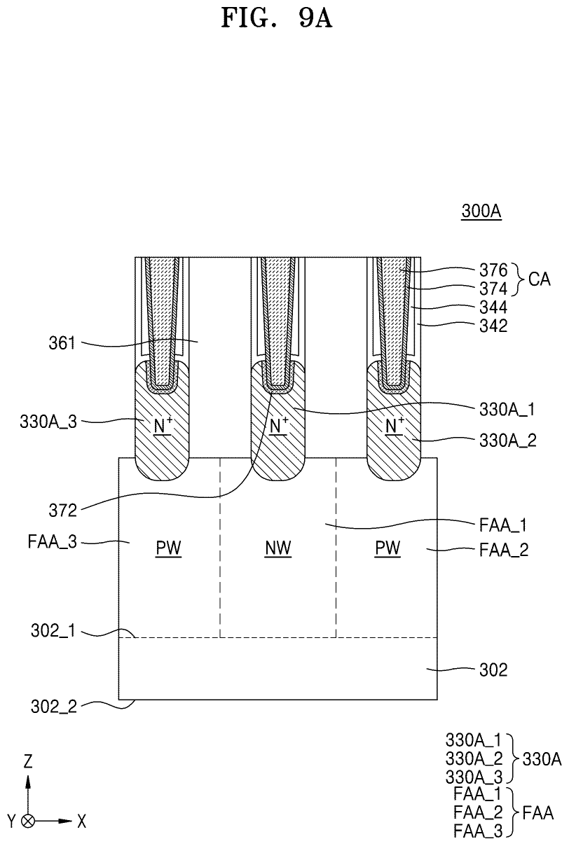

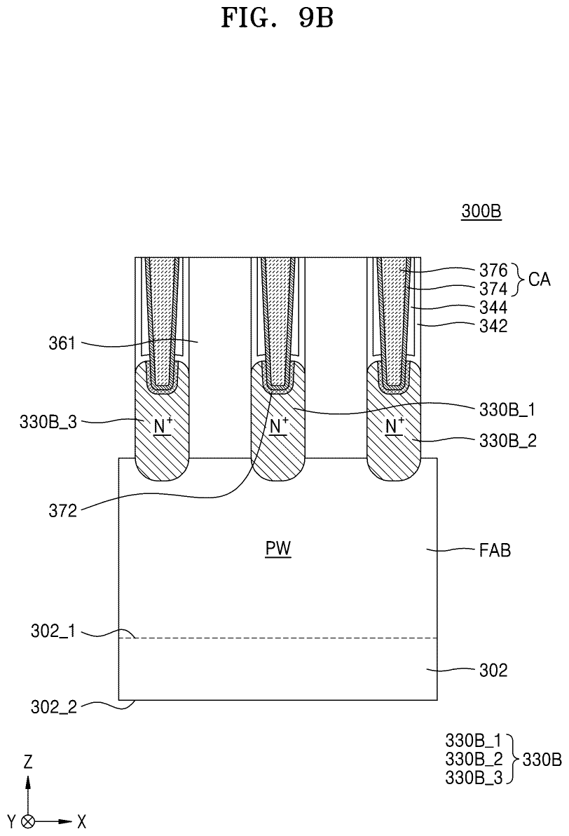

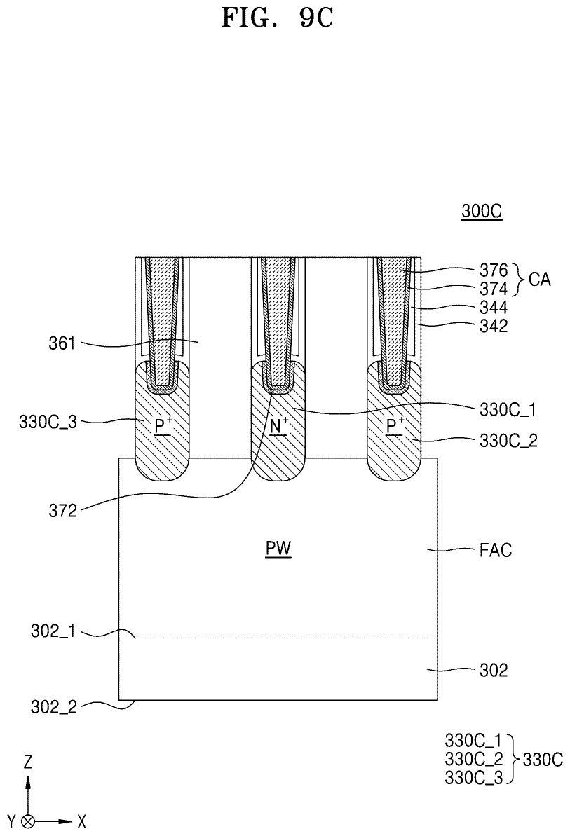

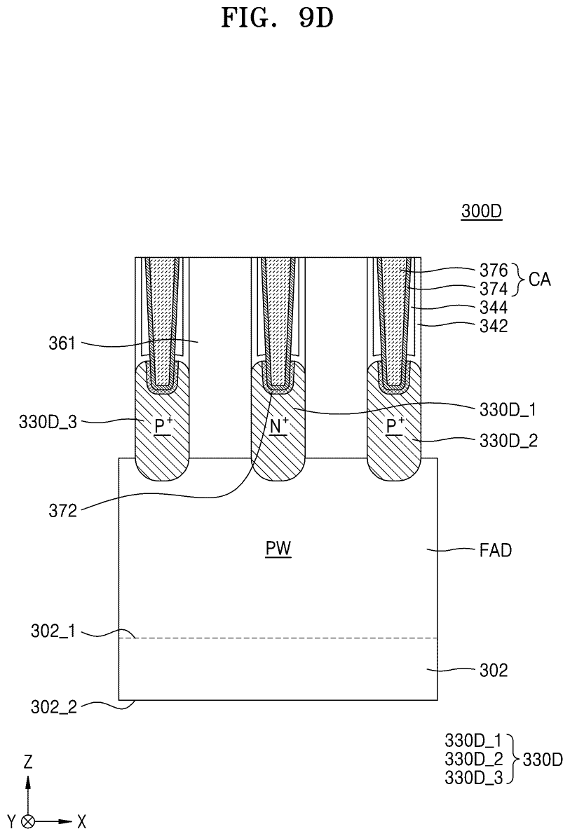

FIGS. 9A and 9D are cross-sectional views of integrated circuit devices 300A, 300B, 300C, and 300D according to embodiments of the present inventive concept. Differences from the integrated circuit device 100 described with reference to FIGS. 1, 2A, and 2B are mainly described, and redundant descriptions may be omitted or briefly discussed.

Referring to FIG. 9A, the integrated circuit device 300A may include a first fin-type active area FAA extending on a substrate 302 in the first horizontal direction (X direction). The fin-type active area FAA may include a first area FAA_1, a second area FAA_2, and a third area FAA_3, which are adjacent to each other in the first horizontal direction (X direction), and the second area FAA_2 and the third area FAA_3 may be spaced apart from each other with the first area FAA_1 disposed therebetween.

A plurality of source/drain areas 330A may be formed on the fin-type active area FAA. A first source/drain area 330A_1 may be formed on the first area FAA_1, and a second source/drain area 330A_2 may be formed on the second area FAA_2. A third source/drain area 330A_3 may be formed on the third area FAA_3.

In embodiments of the present inventive concept, the first area FAA_1 may be doped with an N-type, and the second area FAA_2 and the third area FAA_3 may each be doped with a P-type. The first source/drain area 330A_1, a second source/drain area 330A_2, and a third source/drain area 330A_3 may all be doped with an N-type.

The first area FAA_1 may be doped with an N-type at low concentration (N well), and the second area FAA_2 and the third area FAA_3 may each be doped with a P-type at low concentration (P well). Each of the first source/drain area 330A_1, the second source/drain area 330A_2, and the third source/drain area 330A_3 may be doped with an N-type at a higher concentration (N⁺) than the concentration of each of the first area FAA_1, the second area FAA_2, and/or the third area FAA_3.

Referring to FIG. 9B, the integrated circuit device 300B may include a fin-type active area FAB extending on a substrate 302 in the first horizontal direction (X direction). A plurality of source/drain areas 330B may be formed on the fin-type active area FAB. A first source/drain area 330B_1, a second source/drain area 330B_2, and a third source/drain area 330B_3 may be formed on the fin-type active area FAB.

In embodiments of the present inventive concept, the fin-type active area FAB may be doped with a P-type. The first source/drain area 330B_1, a second source/drain area 330B_2, and a third source/drain area 330B_3 may all be doped with an N-type.

The fin-type active area FAB may be doped with a P-type at low concentration (P well). The first source/drain area 330A_1, a second source/drain area 330A_2, and a third source/drain area 330A_3 may all be doped with an N-type at a higher concentration (N⁺) than a concentration of the fin-type active area FAB.

Referring to FIG. 9C, the integrated circuit device 300C may include a fin-type active area FAC extending on the substrate 302 in the first horizontal direction (X direction). A plurality of source/drain areas 330C may be formed on the fin-type active area FAC. A first source/drain area 330C_1, a second source/drain area 330C_2, and a third source/drain area 330C_3 may be formed on the fin-type active area FAC.

In embodiments of the present inventive concept, the fin-type active area FAC may be doped with a P-type. The first source/drain area 330C_1, a second source/drain area 330C_2, and a third source/drain area 330C_3 may all be doped with a P-type. For example, the second source/drain area 330C_2 and the third source/drain area 330C_3, which are doped with a P-type, may be spaced apart from each other with the first source/drain area 330C_1, which is doped with an N-type, disposed therebetween.

The fin-type active area FAC may be doped with a P-type at low concentration (P well). The first source/drain area 330C_1 may be doped with an N-type at a higher concentration (N⁺) than a concentration of the fin-type active area FAC. The second source/drain area 330C_2 and the third source/drain area 330C_3 may be doped with a P-type at a higher concentration (P⁺) than a concentration of the fin-type active area FAC.

Referring to FIG. 9D, the integrated circuit device 300D may include a fin-type active area FAD extending on the substrate 302 in the first horizontal direction (X direction). A plurality of source/drain areas 330D may be formed on the fin-type active area FAD. A first source/drain area 330D_1, a second source/drain area 330D_2, and a third source/drain area 330D_3 may be formed on the fin-type active area FAD.

In embodiments of the present inventive concept, the fin-type active area FAD may be doped with a P-type. The first source/drain area 330D_1, a second source/drain area 330D_2, and a third source/drain area 330D_3 may all be doped with a P-type. For example, the second source/drain area 330D_2 and the third source/drain area 330D_3, which are doped with a P-type, may be spaced apart from each other with the first source/drain area 330D_1, which is doped with an N-type, disposed therebetween.

The fin-type active area FAD may be doped with a P-type at low concentration (P well). The first source/drain area 330D_1 may be doped with an N-type at a higher concentration (N⁺) than a concentration of the fin-type active area FAD. The second source/drain area 330D_2 and the third source/drain area 330D_3 may be doped with a P-type at a higher concentration (P⁺) than a concentration of the fin-type active area FAD.

While the present inventive concept has been described with reference to example embodiments thereof, it will be understood by those of ordinary skill in the art that various changes in form and details may be made thereto without departing from the spirit and scope of the present inventive concept.

What is claimed is:

1. An integrated circuit device comprising:
a substrate including a first surface and a second surface that are opposite to each other;
a fin-type active area extending on the first surface of the substrate in a first horizontal direction, and including a first area and a second area that are adjacent to each other in the first horizontal direction;
a first source/drain area arranged on the first area of the fin-type active area;
a second source/drain area arranged on the second area of the fin-type active area; and
a first filling insulating layer, which extends in a second horizontal direction crossing the first horizontal direction, between the first source/drain area and the second source/drain area,
wherein the first area of the fin-type active area comprises a first conductivity type,
wherein the second area of the fin-type active area comprises a second conductivity type that is different from the first conductivity type, and
wherein a boundary between the first area and the second area of the fin-type active area comprises a portion that is substantially perpendicular to the first horizontal direction, and overlaps the filling insulating layer.

2. The integrated circuit device of claim 1,
further comprising a plurality of nanosheets in contact with the first source/drain area and the second source/drain area, and disposed between the first source/drain area and the second source/drain area,
wherein the filling insulating layer surrounds each of the plurality of nanosheets.

3. The integrated circuit device of claim 1, wherein the first source/drain area comprises the first conductivity type, and the second source/drain area comprises the second conductivity type.

4. The integrated circuit device of claim 1, wherein a current path is formed in the fin-type active area in the first horizontal direction.

5. The integrated circuit device of claim 1,
further comprising a power pad and a ground pad, each of which are arranged on the second surface of the substrate,
wherein the integrated circuit device is configured to allow a current to flow between the first area and the second area when a voltage is applied to the power pad.

6. The integrated circuit device of claim 5,
wherein the first conductivity type comprises an N-type, and the second conductivity type comprises a P-type, and
wherein a current path is formed from the first area to the second area in the fin-type active area.

7. The integrated circuit device of claim 1, further comprising:
a third area spaced apart from the second area with the first area disposed therebetween, wherein the third area is adjacent to the first area; and
a third source/drain area arranged on the third area of the fin-type active area,
wherein the third area comprises the second conductivity type, and
wherein a boundary between the first area and the third area of the fin-type active area comprises a portion that is substantially perpendicular to the first horizontal direction.

8. The integrated circuit device of claim 1, wherein both the first source/drain area and the second source/drain area comprise a first conductivity type or a second conductivity type.

9. An integrated circuit device comprising:
a substrate including a first surface and a second surface that are opposite to each other;
a fin-type active area extending on the first surface of the substrate in a first horizontal direction, and including a first area and a second area that are adjacent to each other in the first horizontal direction;
a first source/drain area arranged on the first area of the fin-type active area;
a second source/drain area arranged on the second area of the fin-type active area;
a filling insulating layer, which extends in a second horizontal direction crossing the first horizontal direction, between the first source/drain area and the second source/drain area; and
a power pad and a ground pad, each of which are arranged on the second surface of the substrate,
wherein each of the first area of the fin-type active area and the first source/drain area comprises a first conductivity type,
wherein each of the second area of the fin-type active area and the second source/drain area comprises a second conductivity type that is different from the first conductivity type, and
wherein a current path is formed in the fin-type active area in the first horizontal direction.

10. The integrated circuit device of claim 9, further comprising:
a backside insulating layer arranged on the second surface of the substrate;
a first through electrode penetrating the backside insulating layer and connected to the power pad;
a second through electrode penetrating the backside insulating layer and connected to the ground pad;
a first contact connected to the first source/drain area; and
a second contact connected to the second source/drain area.

11. The integrated circuit device of claim 10, wherein the integrated circuit device is configured to allow current to flow from the first through electrode to the first source/drain area via the first contact when a voltage is applied to the power pad.

12. The integrated circuit device of claim 10, wherein the integrated circuit is configured to allow current to flow from the second source/drain area to the second through electrode via the second contact.

13. The integrated circuit device of claim 9,
wherein the first conductivity type comprises an N-type, and the second conductivity type comprises a P-type, and
wherein a current path is formed from the first area to the second area in the fin-type active area.

14. The integrated circuit device of claim 9,
wherein the first area of the fin-type active area is doped at a first concentration,
wherein the first source/drain area is doped at a second concentration that is higher than the first concentration,
wherein the second area of the fin-type active area is doped at a third concentration, and
wherein the second source/drain area is doped at a fourth concentration that is higher than the third concentration.

15. The integrated circuit device of claim 9, wherein a boundary between the first area and the second area of the fin-type active area comprises a portion that is substantially perpendicular to the first horizontal direction, and overlaps the filling insulating layer.

16. An integrated circuit device comprising:
a substrate including a first surface and a second surface that are opposite to each other;
a fin-type active area extending on the first surface of the substrate in a first horizontal direction, wherein the fin-type active area comprises a first area, a second area, and a third area that is spaced apart from the second area with the first area disposed therebetween, wherein the first, second and third areas are arranged in the first horizontal direction;
a first source/drain area arranged on the first area of the fin-type active area;
a second source/drain area arranged on the second area of the fin-type active area;
a third source/drain area arranged on the third area of the fin-type active area;
a filling insulating layer extending between the first source/drain area and the second source/drain area and between the second source/drain area and the third source/drain area; and
a power pad and a ground pad, each of which are arranged on the second surface of the substrate,
wherein the first area of the fin-type active area comprises a first conductivity type,
wherein each of the second area and the third area of the fin-type active area comprises a second conductivity type that is different from the first conductivity type,
wherein the first source/drain area comprises the first conductivity type,
wherein each of the second source/drain area and the third source/drain area comprises the second conductivity type, and
wherein each of a boundary between the first area and the second area and a boundary between the first area and the third area of the fin-type active area comprises a portion that is substantially perpendicular to the first horizontal direction, and overlaps the filling insulating layer.

17. The integrated circuit device of claim 16,
further comprising a plurality of nanosheets in contact with the first source/drain area and the second source/drain area, and disposed between the first source/drain area and the second source/drain area,
wherein the filling insulating layer surrounds each of the plurality of nanosheets.

18. The integrated circuit device of claim 16, wherein a current path is formed in the fin-type active area in the first horizontal direction.

19. The integrated circuit device of claim 16, wherein the integrated circuit device is configured to allow current to flow between the first area and the second area and between the first area and the third area when a voltage is applied to the power pad.

20. The integrated circuit device of claim 19,
wherein the first conductivity type comprises an N-type, and the second conductivity type comprises a P-type,
wherein a current path is formed from the first area to the second area, and
wherein a current path is formed from the first area to the third area.
